(19) United States
(12) Patent Application Publication
(10) Pub. No.: US 2026/0206242 A1
(43) Pub. Date: Jul. 16, 2026

(54) CAPACITOR AND METHOD OF MANUFACTURING THE SAME

(71) Applicant: ELSPES Inc., Daejeon (KR)

(72) Inventors: Tae Dong KIM, Hwaseong-si (KR); Ui Hwan KIM, Hwaseong-si (KR); Yeong Lyeol PARK, Yongin-si (KR); Hee Il CHAE, Hwaseong-si (KR); Seung Tae LEE, Cheonan-si (KR); Dong Ki LEE, Hwaseong-si (KR)

(21) Appl. No.: 19/416,616

(22) Filed: Dec. 11, 2025

(30) Foreign Application Priority Data
Jan. 16, 2025 (KR) 10-2025-0006986

(51) Int. Cl. H10D 1/68; H10D 1/00; H10D 80/20; H10W 46/00; H10W 80/00; H10W 90/20

(52) U.S. Cl. CPC H10D 1/716; H10D 1/042; H10D 80/215; H10W 46/301; H10W 80/327; H10W 90/297

(57) ABSTRACT

The present disclosure relates to a capacitor and a method of manufacturing the same. A capacitor of the present disclosure includes a first substrate, a second substrate disposed on the first substrate, a first trench capacitor disposed on an upper surface of the first substrate, a second trench capacitor disposed on one surface of the second substrate, a first metal layer connected to the first trench capacitor, a second metal layer connected to the second trench capacitor, a plurality of through-silicon vias (TSVs) passing through the second substrate, and a metal pad layer disposed on the other surface opposite to the one surface of the second substrate, wherein the upper surface and the one surface are disposed to face each other, and each of the plurality of TSVs directly connects one of the first metal layer and the second metal layer to the metal pad layer in a direction perpendicular to the one surface. The capacitor may have higher equivalent capacitance by including a first trench capacitor and a second trench capacitor, which are connected in parallel.

### CROSS-REFERENCE TO RELATED APPLICATION

This application claims priority to and the benefit of Korean Patent Application No. 2025-0006986, filed on Jan. 16, 2025, the disclosure of which is incorporated herein by reference in its entirety.

### BACKGROUND

### 1. Field of the Invention

The present disclosure relates to a capacitor and a method of manufacturing the same, and more particularly, to a stacked trench capacitor and a method of manufacturing the same.

### 2. Discussion of Related Art

Recently, electronic devices have been evolving toward higher capacity and higher integration. In particular, with the advent of the 5G era and the enhanced performance of portable electronic devices, the number of passive components installed on portable electronic devices is increasing, and higher capacity is required. On the other hand, due to the miniaturization of electronic devices, the mounting area for passive components such as capacitors and inductors is decreasing, and accordingly, there is a growing demand for miniaturization and high integration of passive components.

Accordingly, a trench capacitor vertically formed inside a semiconductor substrate has been proposed. A trench capacitor may have higher capacitance in the same plane area by securing a surface area between electrodes in a direction perpendicular to a substrate. However, there are many technical difficulties and limitations in further improving the capacitance per unit area of trench capacitors. In particular, in a method of digging a trench to be deeper or forming an upper structure to be higher to increase a vertical length of a trench capacitor, a process of fabricating such a structure is difficult, structural risks are increased, and it also extremely difficult to alternately deposit metal layers and insulating layers in such a structure.

Therefore, there has been a need for a technology for solving the above-described problems.

Meanwhile, the information in the background art described above was obtained by the inventors for the purpose of developing the present disclosure or was obtained during the process of developing the present disclosure. As such, it is to be appreciated that this information did not necessarily belong to the public domain before the patent filing date of the present disclosure.

### RELATED ART DOCUMENTS

### Patent Documents

(Patent Document 1) Korean Laid-Open Patent No. 2020-0064426 (Jun. 8, 2020).

### SUMMARY OF THE INVENTION

The present disclosure is directed to reducing or eliminating structural risks that may occur during a manufacturing process when a trench is dug to be deeper than an existing trench capacitor.

The present disclosure is also directed to providing a capacitor and a method of manufacturing the same which are capable of overcoming limitations associated with increasing capacitance or current/charge density in existing trench capacitors.

The present disclosure is also directed to solving alignment difficulties, issues, or misalignment problems that may occur when a plurality of trench capacitors are bonded in multiple layers.

The objects of the present disclosure are not limited to those described above, and other objects that are not described may become apparent to those of ordinary skill in the art based on the following descriptions.

According to an aspect of the present disclosure, there is provided a capacitor including a first substrate, a second substrate disposed on the first substrate, a first trench capacitor disposed on the upper surface of the first substrate, a second trench capacitor disposed on one surface of the second substrate, a first metal layer connected to the first trench capacitor, a second metal layer connected to the second trench capacitor, a plurality of through-silicon vias (TSVs) passing through the second substrate, and a metal pad layer disposed on the other surface opposite to the one surface of the second substrate, wherein the upper surface and the one surface are disposed to face each other, and each of the plurality of TSVs directly connects one of the first metal layer and the second metal layer to the metal pad layer in a direction perpendicular to the one surface.

The first metal layer may include a first metal pattern connected to a second electrode of the first trench capacitor and a second metal pattern connected to a first electrode of the first trench capacitor, the second metal layer may include a third metal pattern connected to a second electrode of the second trench capacitor and a fourth metal pattern connected to a first electrode of the second trench capacitor, and the plurality of TSVs may include a first TSV connected to the first metal pattern, a second TSV connected to the second metal pattern, a third TSV connected to the third metal pattern, and a fourth TSV connected to the fourth metal pattern.

Each of the first trench capacitor and the second trench capacitor may further include a third electrode and a fourth electrode, the first metal pattern may be connected to the fourth electrode of the first trench capacitor, the second metal pattern may be connected to the third electrode of the first trench capacitor, the third metal pattern may be connected to the fourth electrode of the second trench capacitor, and the fourth metal pattern may be connected to the third electrode of the second trench capacitor.

The metal pad layer may include a plurality of pad connection lines, and the plurality of pad connection lines may be disposed to overlap the first trench capacitor and the second trench capacitor in the direction perpendicular to the one surface, may electrically connect the first TSV and the third TSV, and may electrically connect the second TSV and the fourth TSV.

The capacitor may further include openings passing through the second trench capacitor in the direction perpendicular to the one surface, and the plurality of TSVs may be disposed to pass through the openings.

According to another aspect of the present disclosure, there is provided a capacitor including a first substrate, a second substrate disposed on the first substrate, a first trench capacitor disposed on an upper surface of the first substrate, a second trench capacitor disposed on one surface of the second substrate, a first metal layer connected to the first trench capacitor, a second metal layer connected to the second trench capacitor, a third metal layer connected to the first metal layer, a fourth metal layer connected to the second metal layer, a plurality of TSVs passing through the second substrate, and a metal pad layer disposed on the other surface opposite to the one surface of the second substrate, wherein the upper surface and the one surface are disposed to face each other, and each of the plurality of TSVs directly connects one of the third metal layer and the fourth metal layer to the metal pad layer in a direction perpendicular to the one surface.

The first metal layer may include a first metal pattern connected to a second electrode of the first trench capacitor and a second metal pattern connected to a first electrode of the first trench capacitor, the second metal layer may include a third metal pattern connected to a second electrode of the second trench capacitor and a fourth metal pattern connected to a first electrode of the second trench capacitor, the third metal layer may include a fifth metal pattern connected to the first metal pattern and a sixth metal pattern connected to the second metal pattern, the fourth metal layer may include a seventh metal pattern connected to the third metal pattern and an eighth metal pattern connected to the fourth metal pattern, and the plurality of TSVs may include a fifth TSV connected to the fifth metal pattern, a sixth TSV connected to the sixth metal pattern, a seventh TSV connected to the seventh metal pattern, and an eighth TSV connected to the eighth metal pattern.

Each of the first trench capacitor and the second trench capacitor may further include a third electrode and a fourth electrode, the first metal pattern may be connected to the fourth electrode of the first trench capacitor, the second metal pattern may be connected to the third electrode of the first trench capacitor, the third metal pattern may be connected to the fourth electrode of the second trench capacitor, and the fourth metal pattern may be connected to the third electrode of the second trench capacitor.

The metal pad layer may include a plurality of pad connection lines, and the plurality of pad connection lines may be disposed to overlap the first trench capacitor and the second trench capacitor in the direction perpendicular to the one surface, may electrically connect the fifth TSV and the seventh TSV, and may electrically connect the sixth TSV and the eighth TSV.

The capacitor may further include openings passing through the second trench capacitor in the direction perpendicular to the one surface, and the plurality of TSVs may be disposed to pass through the openings.

According to still another aspect of the present disclosure, there is provided a method of manufacturing a capacitor, the method including forming grooves in an upper surface of a first substrate and one surface of a second substrate, forming a first trench capacitor on the upper surface and forming a second trench capacitor on the one surface, etching portions of the second trench capacitor to form openings passing through the second trench capacitor, forming a first dielectric layer on the first trench capacitor and forming a second dielectric layer on the second trench capacitor, forming a through-hole in each of the first dielectric layer and the second dielectric layer, forming a first metal layer on the first dielectric layer to cover the through-hole and connect to the first trench capacitor, and forming a second metal layer on the second dielectric layer to cover the through-hole and connect to the second trench capacitor, patterning each of the first metal layer and the second metal layer, forming a third dielectric layer to cover the first metal layer on the first dielectric layer, and forming a fourth dielectric layer to cover the second metal layer on the second dielectric layer, bonding the third dielectric layer and the fourth dielectric layer such that the upper surface and the one surface face each other, reducing a thickness of the second substrate from the other surface opposite to the one surface, forming a plurality of TSVs passing through the second substrate, and forming a metal pad layer connected to the plurality of TSVs on the other surface.

The forming of the grooves may include forming an alignment key in a scribe lane of the second substrate.

The forming of the openings may include etching the second trench capacitor using the alignment key.

The forming of the plurality of TSVs may include sensing the alignment key on the other surface, recognizing positions, at which the openings are formed, based on a position of the alignment key, and forming the plurality of TSVs at the positions at which the openings are formed.

The forming of the TSVs may include sensing the second trench capacitor on the other surface, recognizing positions, at which the openings are formed, based on the position of the sensed second trench capacitor, and forming the plurality of TSVs at the positions at which the openings are formed.

The bonding of the third dielectric layer and the fourth dielectric layer may include arranging an adhesive layer on the third dielectric layer, and bonding the first substrate and the second substrate to each other such that the fourth dielectric layer is positioned on the adhesive layer.

According to yet another aspect of the present disclosure, there is provided a method of manufacturing a capacitor, the method including forming grooves in an upper surface of a first substrate and one surface of a second substrate, forming a first trench capacitor on the upper surface and forming a second trench capacitor on the one surface, etching portions of the second trench capacitor to form openings passing through the second trench capacitor, forming a first dielectric layer on the first trench capacitor and forming a second dielectric layer on the second trench capacitor, forming a first through-hole in each of the first dielectric layer and the second dielectric layer, forming a first metal layer on the first dielectric layer to cover the first through-hole and connect to the first trench capacitor, and forming a second metal layer on the second dielectric layer to cover the first through-hole and connect to the second trench capacitor, patterning each of the first metal layer and the second metal layer, forming a third dielectric layer to cover the first metal layer on the first dielectric layer, and forming a fourth dielectric layer to cover the second metal layer on the second dielectric layer, forming a second through-hole in each of the third dielectric layer and the fourth dielectric layer, forming a third metal layer on the third dielectric layer to cover the second through-hole and connect to the first metal layer, and forming a fourth metal layer on the fourth dielectric layer to cover the second through-hole and connect to the second metal layer, patterning the third metal layer and the fourth metal layer, forming a fifth dielectric layer to cover the third metal layer on the third dielectric layer, and forming a sixth dielectric layer to cover the fourth metal layer on the fourth dielectric layer, bonding the fifth dielectric layer and the sixth dielectric layer such that the upper surface and the one surface face each other, reducing a thickness of the second substrate from the other surface opposite to the one surface, forming a plurality of TSVs passing through the second substrate, and forming a metal pad layer connected to the plurality of TSVs on the other surface.

The forming of the grooves may include forming an alignment key in a scribe lane of the second substrate.

The forming of the openings may include etching the second trench capacitor using the alignment key.

The forming of the plurality of TSVs may include sensing the alignment key on the other surface, recognizing positions, at which the openings are formed, based on a position of the alignment key, and forming the plurality of TSVs at the positions at which the openings are formed.

The forming of the TSVs may include sensing the second trench capacitor on the other surface, recognizing positions, at which the openings are formed, based on the position of the sensed second trench capacitor, and forming the plurality of TSVs at the positions at which the openings are formed.

The bonding of the fifth dielectric layer and the sixth dielectric layer may include arranging an adhesive layer on the fifth dielectric layer, and bonding the first substrate and the second substrate to each other such that the sixth dielectric layer is positioned on the adhesive layer.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a top view of a capacitor according to one embodiment of the present disclosure;

FIG. 2 is a cross-sectional view of the capacitor of FIG. 1 along line II-II';

FIG. 3 is a top view for describing a method of forming grooves in a first substrate and a second substrate of a capacitor according to one embodiment of the present disclosure;

FIG. 4 is a cross-sectional view for describing the method of forming grooves in a first substrate and a second substrate of FIG. 3;

FIG. 5 is a top view for describing a method of manufacturing an alignment key on a second substrate of a capacitor according to one embodiment of the present disclosure;

FIG. 6 is a cross-sectional view of a second substrate of FIG. 5 along line VI-VI';

FIG. 7 is a cross-sectional view illustrating a method of manufacturing a first trench capacitor and a second trench capacitor according to one embodiment of the present disclosure;

FIG. 8 is a top view for describing a method of manufacturing a first metal layer and a second metal layer of a capacitor according to one embodiment of the present disclosure;

FIG. 9 is a cross-sectional view for describing the method of manufacturing a first metal layer and a second metal layer of FIG. 8;

FIG. 10 is a top view for describing a method of bonding a first substrate and a second substrate of a capacitor according to one embodiment of the present disclosure;

FIG. 11 is a cross-sectional view for describing the method of bonding a first substrate and a second substrate of FIG. 10;

FIG. 12 is a cross-sectional view for describing a method of manufacturing a plurality of through-silicon vias (TSVs) and a metal pad layer of a capacitor according to one embodiment of the present disclosure;

FIG. 13 is a top view of a capacitor according to another embodiment of the present disclosure;

FIG. 14 is a cross-sectional view of the capacitor of FIG. 13 along line XIV-XIV';

FIG. 15 is a cross-sectional view for describing a method of manufacturing a first metal layer and a second metal layer of a capacitor according to another embodiment of the present disclosure;

FIG. 16 is a top view illustrating a method of manufacturing a third metal layer and a fourth metal layer of a capacitor according to another embodiment of the present disclosure;

FIG. 17 is a cross-sectional view for describing the method of manufacturing a third metal layer and a fourth metal layer of FIG. 16;

FIG. 18 is a top view for describing a method of bonding a first substrate and a second substrate of a capacitor according to another embodiment of the present disclosure;

FIG. 19 is a cross-sectional view for describing the method of bonding the first substrate and the second substrate of FIG. 18; and

FIG. 20 is a cross-sectional view for describing a method of manufacturing a plurality of TSVs and a metal pad layer of a capacitor according to another embodiment of the present disclosure.

### DETAILED DESCRIPTION OF EXEMPLARY EMBODIMENTS

The advantages and features of the present disclosure and methods of accomplishing the same will become apparent from the following description of embodiments in detail, taken in conjunction with the accompanying drawings. However, the present disclosure is not limited to the embodiments disclosed herein but will be implemented in various forms. The embodiments are provided so that the present disclosure is completely disclosed, and a person of ordinary skilled in the art can fully understand the scope of the present disclosure. Therefore, the present disclosure will be defined only by the scope of the appended claims.

A shape, a size, a ratio, an angle, and a number disclosed in the drawings for describing embodiments of the present disclosure are merely an example, and thus, the present disclosure is not limited to the illustrated details. In addition, in describing the present disclosure, when it is determined that the specific description of the known related art unnecessarily obscures the gist of the present disclosure, the detailed description thereof will be omitted. Terms such as “including,” “having,” and “consist of” used herein are generally intended to allow other components to be added unless the terms are used with the term “only.” Any references to a singular form may include a plural form unless expressly stated otherwise.

Components are interpreted to include an ordinary error range even when not expressly stated.

Although the terms “first,” “second,” and the like are used to describe various components, these components are not limited by these terms. These terms are merely used to distinguish one component from another. Therefore, a first component to be described below may be a second component in a technical concept of the present disclosure.

Unless otherwise specified, like reference numerals refer to like elements throughout the specification.

The features of various embodiments of the present disclosure can be partially or entirely adhered to or combined with each other and can be interlocked and operated in technically various ways as understood by those skilled in the art, and the embodiments can be carried out independently of or in association with each other.

Hereinafter, the present disclosure will be described in detail with reference to the accompanying drawings.

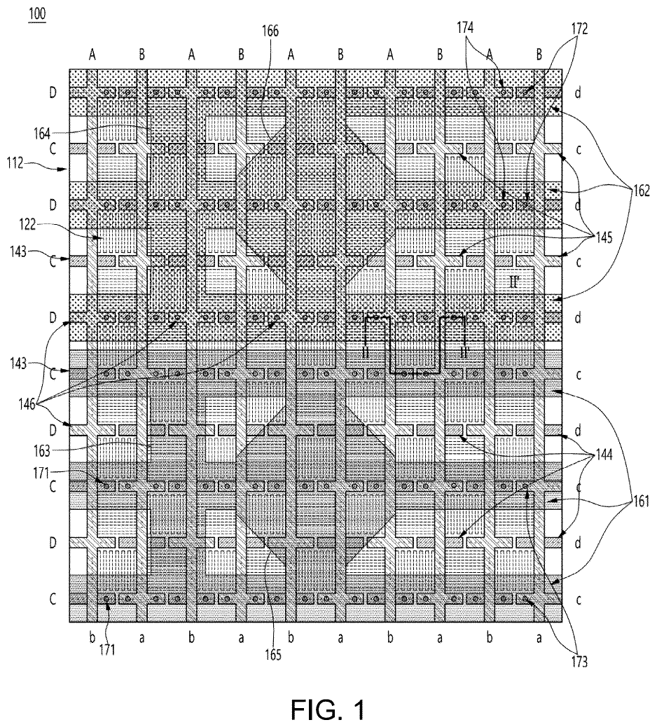

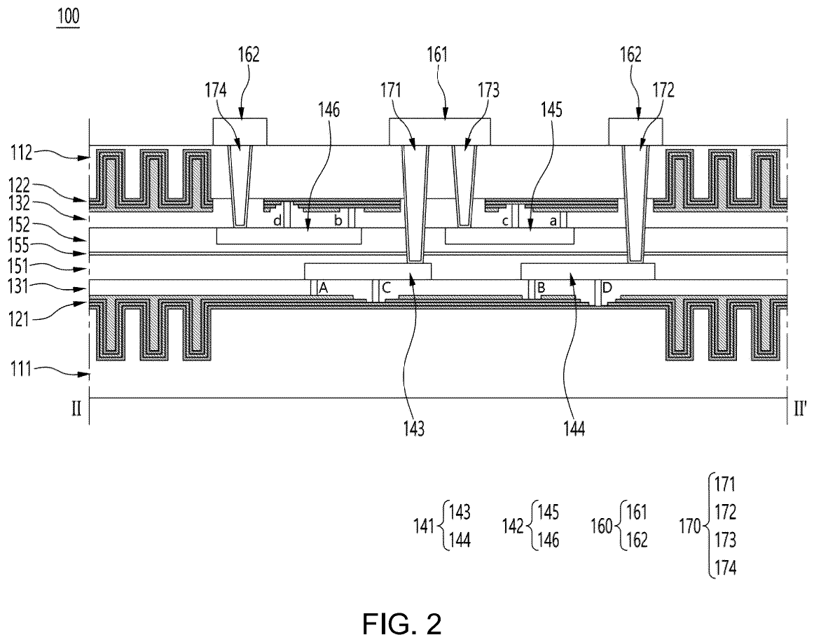

FIG. 1 is a top view of a capacitor according to one embodiment of the present disclosure. FIG. 2 is a cross-sectional view of the capacitor of FIG. 1 along line II-II'.

Referring to FIGS. 1 and 2, a capacitor 100 includes a first substrate 111, a second substrate 112, a first trench capacitor 121, a second trench capacitor 122, a first dielectric layer 131, a second dielectric layer 132, a first metal layer 141, a second metal layer 142, a third dielectric layer 151, a fourth dielectric layer 152, a bonding layer 155, a metal pad layer 160, and a through-silicon via (TSV) 170.

The first substrate 111 and the second substrate 112 may include various materials according to the type and required characteristics of the capacitor 100. For example, the first substrate 111 and the second substrate 112 may include Si, SiC, Al₂O₃, GaAs, GaN, InP, InAs, or InSb. Preferably, the first substrate 111 and the second substrate 112 may be Si wafers.

Each of the first substrate 111 and the second substrate 112 may include a groove formed in one surface thereof. Specifically, a plurality of trenches may be disposed in each of an upper surface of the first substrate 111 and one surface of the second substrate 112. More specifically, the upper surface of the first substrate 111 and one surface of the second substrate 112 may be disposed to face each other, and the plurality of trenches may be disposed in each of the upper surface of the first substrate 111 and one surface of the second substrate 112.

The plurality of trenches may be arranged in various shapes in the first substrate 111 and the second substrate 112. Specifically, the plurality of trenches may include a plurality of trenches extending horizontally and a plurality of trenches extending vertically in a plane view of each of the first substrate 111 and the second substrate 112. More specifically, as shown in FIG. 1, the plurality of trenches may have a form in which a horizontal trench unit including a plurality of trenches extending horizontally and a vertical trench unit including a plurality of trenches extending vertically are alternately arranged in a plane view of each of the first substrate 111 and the second substrate 112.

The plurality of trenches disposed in the first substrate 111 and the plurality of trenches disposed in the second substrate 112 may have various shapes. Preferably, the plurality of trenches disposed in the first substrate 111 and the plurality of trenches disposed in the second substrate 112 may have the same shape. That is, trenches with the same shape may be formed in the first substrate 111 and the second substrate 112 through the same process. In some cases, the plurality of trenches disposed in the first substrate 111 and the plurality of trenches disposed in the second substrate 112 may have different depths, lengths, widths, or intervals.

Capacitors may be disposed within the plurality of trenches of the first substrate 111 and the second substrate 112. Specifically, the first trench capacitor 121 may be disposed on the upper surface of the first substrate 111 and in the plurality of trenches disposed in the upper surface of the first substrate 111, and the second trench capacitor 122 may be disposed on one surface of the second substrate 112 and in the plurality of trenches disposed in one surface of the second substrate 112. More specifically, as shown in FIG. 2, the first trench capacitor 121 may be disposed on the upper surface of the first substrate 111 facing the second substrate 112, and the second trench capacitor 122 may be disposed on one surface of the second substrate 112 facing the first substrate 111. According to various embodiments of the present disclosure, the first trench capacitor 121 may be disposed on the upper surface of the first substrate 111, and the second trench capacitor 122 may be disposed on an upper surface of the second substrate 112. Accordingly, a process of flipping and stacking the second substrate 112 is omitted, thereby simplifying a manufacturing process and reducing a unit cost of a capacitor.

The first trench capacitor 121 and the second trench capacitor 122 may include trench areas and areas in which a trench is not formed. For example, the first trench capacitor 121 may include an area A, an area B, an area C, and an area D in which a trench is not formed, and the second trench capacitor 122 may include an area a, an area b, an area c, and an area d in which a trench is not formed. Specifically, as shown in FIG. 1, the first trench capacitor 121 may include a plurality of areas A and a plurality of areas B extending in a vertical direction in the plane view of the first substrate 111. The plurality of areas A and the plurality of areas B may be alternately arranged in a horizontal direction. In addition, the first trench capacitor 121 may include a plurality of areas C and a plurality of areas D extending in the horizontal direction in the plane view of the first substrate 111. The plurality of areas C and the plurality of areas D may be alternately arranged in the vertical direction. The area a, the area b, the area c, and the area d of the second trench capacitor 122 may have substantially the same arrangement relationship as the area A, the area B, the area C, and the area D of the first trench capacitor 121. That is, a plurality of areas a and a plurality of areas b of the second trench capacitor 122 may extend in the vertical direction and may be alternately arranged in the horizontal direction. In addition, a plurality of areas c and a plurality of areas d of the second trench capacitor 122 may extend in the horizontal direction and may be alternately arranged in the vertical direction.

Widths of the area C and area D of the first trench capacitor 121 may be greater than widths of the area A and area B. Specifically, in the plane view of the first substrate 111, vertical widths of the area C and the area D may be greater than horizontal widths of the area A and the area B. Accordingly, contact holes exposing electrodes located relatively at a low portion of the first trench capacitor 121 may be disposed in the area C and the area D of the first trench capacitor 121. That is, by arranging contact holes, which are formed to be relatively deep and wide, in the area C and the area D with a relatively great width, problems that may occur due to process errors in a contact hole formation process can be prevented, and the contact holes may be formed stably. A size relationship between the area a, the area b, the area c, and the area d of the second trench capacitor 122 may be substantially the same as a size relationship between the area A, the area B, the area C, and the area D of the first trench capacitor 121. That is, in the plane view of the second substrate 112, vertical widths of the area c and the area d of the second trench capacitor 122 may be greater than horizontal widths of the area a and the area b. Accordingly, widths of contact holes disposed in the area c and the area d of the second trench capacitor 122 may be greater than widths of contact holes disposed in the area a and the area b of the second trench capacitor 122.

Referring to FIG. 1, in a direction perpendicular to the first substrate 111, areas in which trenches of the first trench capacitor 121 and the second trench capacitor 122 are not formed may be disposed to overlap each other. For example, the area A of the first trench capacitor 121 and the area b of the second trench capacitor 122 may overlap each other, the area B of the first trench capacitor 121 and the area a of the second trench capacitor 122 may overlap each other, the area C of the first trench capacitor 121 and the area c of the second trench capacitor 122 may overlap each other, and the area D of the first trench capacitor 121 and the area d of the second trench capacitor 122 may overlap each other. In some cases, the area A of the first trench capacitor 121 and the area a of the second trench capacitor 122 may be disposed to overlap each other.

Referring to FIG. 2, the second trench capacitor 122 may include openings. Specifically, a plurality of openings that pass through the second trench capacitor 122 in a direction perpendicular to one surface of the second substrate 112 may be disposed in the second trench capacitor 122. The plurality of openings may be disposed at various positions of the second trench capacitor 122. For example, the plurality of openings may be disposed in each of the area a, the area b, the area c, and the area d of the second trench capacitor 122. Preferably, the plurality of openings may be disposed only in the area c and area d of the second trench capacitor 122. Since the area c and area d of the second trench capacitor 122 have a greater width than the area a and area b, the openings disposed in the area c and area d may be formed with a greater width. Accordingly, even when process errors occur at positions of a plurality of TSVs 170 positioned to pass through openings, a problem that the second trench capacitor 122 is in contact with the TSVs 170 can be prevented. In addition, since the opening is formed to be relatively greater than a width of the TSV 170, parasitic effects caused by the proximity between the second trench capacitor 122 and the TSVs 170 can be reduced.

The first trench capacitor 121 and the second trench capacitor 122 each include a first electrode and a second electrode. Specifically, the first trench capacitor 121 and the second trench capacitor 122 may each include the first electrode, a first insulating layer, and the second electrode which are sequentially stacked. That is, the first trench capacitor 121 and the second trench capacitor 122 may each have a metal-insulator-metal (MIM) structure. In some cases, the first trench capacitor 121 and the second trench capacitor 122 may each further include a third electrode and a fourth electrode. Specifically, the first trench capacitor 121 and the second trench capacitor 122 may each have a metal-insulator-metal-insulator-metal-insulator-metal (MIMIMIM) structure in which the first electrode, the first insulating layer, the second electrode, a second insulating layer, the third electrode, a third insulating layer, and the fourth electrode are sequentially stacked. In the present embodiment, a description will be provided based on an example in which the first trench capacitor 121 and the second trench capacitor 122 each have a MIMIMIM structure.

The first electrode, the second electrode, the third electrode, and the fourth electrode of each of the first trench capacitor 121 and the second trench capacitor 122 may include various conductive materials. Specifically, the first to fourth electrodes may include a metal film, a metal oxide film, a metal nitride film, or a metal oxynitride film. For example, the first to fourth electrodes may include TiN, WN, or TaN.

The first insulating layer, the second insulating layer, and the third insulating layer may include various dielectric materials. Specifically, the first to third insulating layers may include silicon oxide, silicon nitride, or a high-dielectric constant (high-k) material. For example, the first to third insulating layers may include SiO₂, Si₃N₄,

### Al₂o₃, Hfo₂, Ta₂o₅, or Zro₂.

In the first trench capacitor 121, the area A, the area B, the area C, and the area D may include different contact holes. Specifically, at least one contact hole exposing any one of the first electrode, the second electrode, the third electrode, and the fourth electrode of the first trench capacitor 121 may be disposed in each of the area A, the area B, the area C, and the area D. For example, an A contact hole in which the fourth electrode of the first trench capacitor 121 is exposed may be disposed in the area A, a B contact hole in which the third electrode of the first trench capacitor 121 is exposed may be disposed in the area B, a C contact hole in which the second electrode of the first trench capacitor 121 is exposed may be disposed in the area C, and a D contact hole in which the first electrode of the first trench capacitor 121 is exposed may be disposed in the area D. In some cases, the fourth electrode of the first trench capacitor 121 may be disposed at an uppermost portion so that a contact hole may not be disposed in the area A of the first trench capacitor 121. A contact hole structural layout of the second trench capacitor 122 may be substantially the same as a contact hole structural layout of the first trench capacitor 121. For example, an a contact hole in which the fourth electrode of the second trench capacitor 122 is exposed may be disposed in the area a, a b contact hole in which the third electrode of the second trench capacitor 122 is exposed may be disposed in the area b, a c contact hole in which the second electrode of the second trench capacitor 122 is exposed may be disposed in the area C, and a d contact hole in which the first electrode of the second trench capacitor 122 is exposed may be disposed in the area D.

Referring to FIG. 2, the first dielectric layer 131 may be disposed to cover the first trench capacitor 121, and the second dielectric layer 132 may be disposed to cover the second trench capacitor 122. Specifically, the first dielectric layer 131 and the second dielectric layer 132 may be disposed between the first trench capacitor 121 and the second trench capacitor 122 to cover the first trench capacitor 121 and the second trench capacitor 122, respectively. That is, as shown in FIG. 2, the first dielectric layer 131 may be disposed on the first trench capacitor 121, the second dielectric layer 132 may be disposed on the first dielectric layer 131, and the second trench capacitor 122 may be disposed on the second dielectric layer 132.

The first dielectric layer 131 and the second dielectric layer 132 may include various materials. For example, the first dielectric layer 131 and the second dielectric layer 132 may include SiO₂, Si₃N₄, SiOₓN_{y}, or a low-dielectric constant (low-k) material.

A plurality of first through-holes may be disposed in each of the first dielectric layer 131 and the second dielectric layer 132. Specifically, the plurality of first through-holes may be disposed between the first metal layer 141 and the first trench capacitor 121 and between the second metal layer 142 and the second trench capacitor 122. More specifically, the first through-hole may be disposed between the first metal layer 141 and each of the first to fourth electrodes of the first trench capacitor 121 and between the second metal layer 142 and each of the first to fourth electrodes of the second trench capacitor 122.

Referring to FIGS. 1 and 2, the plurality of first through-holes may be disposed in an area in which trenches of the first trench capacitor 121 and the second trench capacitor 122 are not formed. Specifically, the plurality of first through-holes may include a first A through-hole connected to the fourth electrode of the A contact hole of the first trench capacitor 121, a first B through-hole connected to the third electrode of the B contact hole, a first C through-hole connected to the second electrode of the C contact hole, and a first D through-hole connected to the first electrode of the D contact hole, a first a through-hole connected to the fourth electrode of the a contact hole of the second trench capacitor 122, a first b through-hole connected to the third electrode of the b contact hole, a first c through-hole connected to the second electrode of the c contact hole, and a first d through-hole connected to the first electrode of the d contact hole.

A conductive material may be disposed within the plurality of first through-holes. The plurality of first through-holes may be conductive vias that may electrically connect the first to fourth electrodes of the first trench capacitor 121 to the first metal layer 141 and may electrically connect the first to fourth electrodes of the second trench capacitor 122 to the second metal layer 142.

Referring to FIG. 2, the first metal layer 141 may be disposed on an upper surface of the first dielectric layer 131, and the second metal layer 142 may be disposed on one surface of the second dielectric layer 132. Specifically, the first metal layer 141 may be disposed on the upper surface of the first dielectric layer 131 facing the second substrate 112, and the second metal layer 142 may be disposed on one surface of a second dielectric layer 132 facing the first substrate 111. That is, as shown in FIG. 2, the first metal layer 141 may be directly disposed on the first dielectric layer 131, the second metal layer 142 may be directly disposed on the first metal layer 141, and the second dielectric layer 132 may be directly disposed on the second metal layer 142.

Referring to FIGS. 1 and 2, the first metal layer 141 may include a plurality of first metal patterns 143 and a plurality of second metal patterns 144 which are disposed to be spaced apart from each other. Specifically, the first metal layer 141 may include the first metal pattern 143 connected to the second electrode of the first trench capacitor 121 and the second metal pattern 144 connected to the first electrode of the first trench capacitor 121. In some cases, the first metal pattern 143 may be connected to the fourth electrode of the first trench capacitor 121, and the second metal pattern 144 may be connected to the third electrode of the first trench capacitor 121.

In addition, the second metal layer 142 may include a plurality of third metal patterns 145 and a plurality of fourth metal patterns 146 which are disposed to be spaced apart from each other. Specifically, the second metal layer 142 may include a third metal pattern 145 connected to the second electrode of the second trench capacitor 122 and a fourth metal pattern 146 connected to the first electrode of the second trench capacitor 122. In some cases, the third metal pattern 145 may be connected to the fourth electrode of the second trench capacitor 122, and the fourth metal pattern 146 may be connected to the third electrode of the second trench capacitor 122.

The first metal pattern 143, the second metal pattern 144, the third metal pattern 145, and the fourth metal pattern 146 may have various shapes. For example, as shown in FIG. 1, the first to fourth metal patterns 143, 144, 145, and 146 may each include a long pattern portion extending in one direction and a short pattern portion extending in a direction perpendicular to the one direction. Specifically, the first to fourth metal patterns 143, 144, 145, and 146 may have a shape in which a plurality of short pattern portions are disposed in one long pattern portion. In some cases, the first metal pattern 143 and the third metal pattern 145 may have the same shape, and the second metal pattern 144 and the fourth metal pattern 146 may have the same shape. Accordingly, since the first metal layer 141 and the second metal layer 142 have the same shape, the first metal layer 141 and the second metal layer 142 may be formed through the same process without changes in a mask and process variables in a manufacturing process operation of the first metal layer 141 and the second metal layer 142. Accordingly, by simultaneously performing a process of forming the first metal layer 141 of the first substrate 111 and a process of forming the second metal layer 142 of the second substrate 112 in one chamber, a manufacturing cost and time of the capacitor 100 can be reduced.

According to various embodiments of the present disclosure, lengths of the short pattern portions of the first metal pattern 143 and the second metal pattern 144 in a direction perpendicular to one direction may be greater than lengths of the short pattern portions of the third metal pattern 145 and the fourth metal pattern 146 in a direction perpendicular to one direction. Accordingly, in the direction perpendicular to the first substrate 111, planar areas of the first metal pattern 143 and the second metal pattern 144 that do not overlap the third metal pattern 145 and the fourth metal pattern 146 may increase. Accordingly, by increasing the contact area between the first and second metal patterns 143 and 144 and the TSV 170, the contact stability between the first and second metal patterns 143 and 144 and the TSV 170 and the equivalent series resistance (ESR) of the capacitor 100 can be improved.

Referring to FIG. 1, the plurality of third metal patterns 145 and the plurality of fourth metal patterns 146 may be disposed to be coplanar in one direction. Specifically, the plurality of third metal patterns 145 and the plurality of fourth metal patterns 146 having long pattern portions that extend in the vertical direction may be alternately disposed in the horizontal direction. For example, as shown in FIG. 1, the long pattern portions of the third metal patterns 145 may be disposed to overlap the areas a of the second trench capacitor 122, and the long pattern portions of the fourth metal patterns 146 may be disposed to overlap the areas b of the second trench capacitor 122. In some cases, the short pattern portions of the third metal patterns 145 and the short pattern portions of the fourth metal patterns 146 may be disposed to be misaligned with each other. For example, as shown in FIG. 1, the short pattern portions of the third metal patterns 145 may be disposed to overlap the areas c of the second trench capacitor 122, and the short pattern portions of the fourth metal patterns 146 may be disposed to overlap the areas d of the second trench capacitor 122. Accordingly, parasitic effects that may occur due to the proximity between the short pattern portions of the third metal pattern 145 and the fourth metal pattern 146 can be minimized, and electrical interference can be prevented. In addition, by forming the short pattern portions of the third metal pattern 145 and the fourth metal pattern 146 to be longer, the contact area between the second metal layer 142 and the second trench capacitor 122 and the contact area between the second metal layer 142 and the TSV 170 can be increased, and the ESR of the capacitor 100 can be improved.

An arrangement relationship of the first metal pattern 143 and the second metal pattern 144 may be substantially the same as an arrangement relationship of the third metal pattern 145 and the fourth metal pattern 146. That is, the long pattern portions of the first metal patterns 143 may be disposed to overlap the areas A of the first trench capacitor 121, and the long pattern portions of the second metal patterns 144 may be disposed to overlap the areas B of the first trench capacitor 121. In addition, the short pattern portions of the first metal patterns 143 may be disposed to overlap the areas C of the first trench capacitor 121, and the short pattern portions of the second metal patterns 144 may be disposed to overlap the areas D of the first trench capacitor 121.

Referring to FIGS. 1 and 2, in the direction perpendicular to the first substrate 111, a partial area of the first metal layer 141 and a partial area of the second metal layer 142 may be disposed to overlap each other. Specifically, the long pattern portions of the first metal pattern 143 and the second metal pattern 144 and the long pattern portions of the third metal pattern 145 and the fourth metal pattern 146 may be disposed to overlap each other. For example, the long pattern portion of the first metal pattern 143 disposed in the area A and the fourth metal pattern 146 disposed in the area b may overlap each other in the direction perpendicular to the first substrate 111. Preferably, the short pattern portion of the first metal pattern 143 disposed in the area C and the short pattern portion of the fourth metal pattern 146 disposed in the area d may not overlap each other in the direction perpendicular to the first substrate 111. Accordingly, the first metal layer 141 may include a plurality of short pattern portions that do not overlap the second metal layer 142, thereby securing a plurality of contact areas that may be in contact with the TSV 170. Accordingly, each of the plurality of first metal patterns 143 and the plurality of second metal patterns 144 includes a plurality of contact areas that may be in direct contact with the TSV 170, thereby improving the contact redundancy between the first and second metal patterns 143 and 144 and the metal pad layer 160 and the ESR between the first and second metal patterns 143 and 144 and the metal pad layer 160.

Referring to FIG. 2, the first metal layer 141 may be connected to the first trench capacitor 121, and the second metal layer 142 may be connected to the second trench capacitor 122. Specifically, the first metal pattern 143 may be connected to the fourth electrode of the first trench capacitor 121 through the first A through-hole and may be connected to the second electrode of the first trench capacitor 121 through the first C through-hole. The second metal pattern 144 may be connected to the third electrode of the first trench capacitor 121 through the first B through-hole and may be connected to the first electrode of the first trench capacitor 121 through the first D through-hole. The third metal pattern 145 may be connected to the fourth electrode of the second trench capacitor 122 through the first a through-hole and may be connected to the second electrode of the second trench capacitor 122 through the first c through-hole. The fourth metal pattern 146 may be connected to the third electrode of the second trench capacitor 122 through the first b through-hole and may be connected to the first electrode of the second trench capacitor 122 through the first d through-hole. Accordingly, each of the plurality of first metal patterns 143 connects the second electrode and the fourth electrode of the first trench capacitor 121, and each of the plurality of second metal patterns 144 connects the first electrode and the third electrode of the first trench capacitor 121, thereby increasing the contact area between the first electrode and the third electrode of the first trench capacitor 121 and the contact area between the second electrode and the fourth electrode, and improving the ESR of the capacitor 100.

The third dielectric layer 151 may be disposed to cover the first metal layer 141, and the fourth dielectric layer 152 may be disposed to cover the second metal layer 142. Specifically, the third dielectric layer 151 and the fourth dielectric layer 152 may be disposed between the first metal layer 141 and the second metal layer 142 to cover the first metal layer 141 and the second metal layer 142, respectively. That is, as shown in FIG. 2, the third dielectric layer 151 may be directly disposed on the first metal layer 141, the fourth dielectric layer 152 may be directly disposed on the third dielectric layer 151, and the second metal layer 142 may be directly disposed on the fourth dielectric layer 152.

The third dielectric layer 151 and the fourth dielectric layer 152 may be insulating layers that are substantially the same as the first dielectric layer 131 and the second dielectric layer 132. For example, the third dielectric layer 151 and the fourth dielectric layer 152 may include SiO₂, Si₃N₄, SiOₓN_{y}, or a low-k material.

The third dielectric layer 151 and the fourth dielectric layer 152 may be bonded at the bonding layer 155. For example, the third dielectric layer 151 and the fourth dielectric layer 152 may be bonded at the bonding layer 155 through any one of adhesive bonding, oxide bonding, and fusion bonding. When the third dielectric layer 151 and the fourth dielectric layer 152 are bonded through adhesive bonding, the bonding layer 155 may include an adhesive such as a resin adhesive such as an epoxy resin or an acrylic resin, polyimide, or a silicone adhesive. When the third dielectric layer 151 and the fourth dielectric layer 152 are bonded through oxide bonding or fusion bonding, the bonding layer 155 may include the same material as the third dielectric layer 151 and the fourth dielectric layer 152. Specifically, the third dielectric layer 151 and the fourth dielectric layer 152 are bonded through oxide bonding in which SiO2 is bonded through chemical bonding, thereby preventing damage and mechanical stress due to high temperature and enabling stable bonding.

The metal pad layer 160 may be disposed on the other surface of the second substrate 112. Specifically, the metal pad layer 160 may be disposed on the other surface of the second substrate 112 opposite to one surface on which the second trench capacitor 122 is disposed. That is, as shown in FIG. 2, the metal pad layer 160 may be disposed on the upper surface of the second substrate 112.

Referring to FIG. 1, the metal pad layer 160 may include a plurality of pad connection lines. Specifically, the metal pad layer 160 may include first pad connection lines 161 and second pad connection lines 162 which extend in one direction. Specifically, the metal pad layer 160 may include a plurality of first pad connection lines 161 and a plurality of second pad connection lines 162 which extend in a direction perpendicular to a longitudinal direction of the long pattern portion of the first metal layer 141 and the second metal layer 142. In some cases, the metal pad layer 160 may further include a third pad connection line 163, a fourth pad connection line 164, a first pad 165, and a second pad 166.

The plurality of pad connection lines may be disposed to overlap the first trench capacitor 121 and the second trench capacitor 122 in a direction perpendicular to one surface of the second substrate 112. Specifically, the first pad connection line 161 and the second pad connection line 162 may be disposed to overlap the short pattern portions of the first metal layer 141 and the second metal layer 142. More specifically, the first pad connection lines 161 may be disposed to overlap the short pattern portions of the first metal layer 141 and the second metal layer 142 disposed in the area C, and the second pad connection lines 162 may be disposed to overlap the short pattern portions of the first metal layer 141 and the second metal layer 142 disposed in the area D. Accordingly, the first pad connection line 161 may be connected to a first TSV 171 and a third TSV 173, and the second pad connection line 162 may be connected to a second TSV 172 and a fourth TSV 174. That is, the first pad connection line 161 may be connected to the second electrode and the fourth electrode of the first trench capacitor 121 through the first TSV 171 and may be connected to the second electrode and the fourth electrode of the second trench capacitor 122 through the third TSV 173. The second pad connection line 162 may be connected to the first electrode and the third electrode of the first trench capacitor 121 through the second TSV 172 and may be connected to the first electrode and the third electrode of the second trench capacitor 122 through the fourth TSV 174. Accordingly, since the first and second trench capacitors 121 and 122 are connected in parallel through the first and second pad connection lines 161 and 162, the capacitor 100 may have equivalent capacitance that is the sum of capacitance of the first trench capacitor 121 and capacitance of the second trench capacitor 122.

The plurality of first pad connection lines 161 disposed to overlap the areas D and the plurality of second pad connection lines 162 disposed to overlap the areas C may be alternately arranged. When the plurality of first pad connection lines 161 and the plurality of second pad connection lines 162 are alternately arranged, the plurality of first pad connection lines 161 may be connected to each other in an outer area of the capacitor 100, and the plurality of second pad connection lines 162 may also be connected to each other in the outer area of the capacitor 100. Preferably, as shown in FIG. 1, the first pad connection line 161 may be disposed in each of the areas C located in one area of the second substrate 112, and the second pad connection line 162 may be disposed in each of the areas D located in another area of the second substrate 112.

Accordingly, the plurality of first pad connection lines 161 are connected to each other through at least one third pad connection line 163 or at least one first pad 165 disposed to overlap the first and second trench capacitors 121 and 122 in a direction perpendicular to the second substrate 112, thereby increasing the connection path and contact area between the first pad connection lines 161. Therefore, the ESR between the first and the second trench capacitors 121 and 122 and the first pad connection line 161 can be improved.

Referring to FIG. 1, the third pad connection line 163 and the fourth pad connection line 164 may extend in a direction perpendicular to a direction in which the first pad connection line 161 and the second pad connection line 162 extend. For example, the third pad connection line 163 and the fourth pad connection line 164 may extend along a length direction of the long pattern portion of the first metal layer 141 and the second metal layer 142.

The third pad connection line 163 and the fourth pad connection line 164 may be connected to the first pad connection line 161 and the second pad connection line 162. Specifically, the third pad connection line 163 may be connected to at least one first pad connection line 161, and the fourth pad connection line 164 may be connected to at least one second pad connection line 162. For example, the third pad connection line 163 may connect the plurality of first pad connection lines 161 to each other, and the fourth pad connection line 164 may connect the plurality of second pad connection lines 162 to each other. Accordingly, the plurality of first pad connection lines 161 extending in one direction may be electrically connected to each other, and the plurality of second pad connection lines 162 extending in one direction may be electrically connected to each other. Accordingly, the plurality of pad connection lines may electrically connect the first TSV 171 and the third TSV 173 and may electrically connect the second TSV 172 and the fourth TSV 174.

The third pad connection line 163 and the fourth pad connection line 164 may be disposed to overlap the first trench capacitor 121 and the second trench capacitor 122. Specifically, in the plane view of the first substrate 111, the third pad connection line 163 and the fourth pad connection line 164 may overlap trench areas of the first trench capacitor 121 and the second trench capacitor 122 or may overlap an area in which a trench is not formed. Accordingly, since the third pad connection line 163 and the fourth pad connection line 164 have a wider surface area, the contact area between the first pad connection lines 161, the contact area between the second pad connection lines 162, the contact area between the first pad 165 and the first pad connection lines 161 and the third pad connection lines 163, and the contact area between the second pad 166 and the second pad connection lines 162 and the fourth pad connection lines 164 may increase. Therefore, the ESR between the first trench capacitor 121 and the first pad 165 and the ESR between the second trench capacitor 122 and the second pad 166 may be improved.

The first pad 165 and the second pad 166 may be disposed on the first trench capacitor 121 and the second trench capacitor 122. Specifically, the first pad 165 may be disposed in one area of the second substrate 112, and the second pad 166 may be disposed in the other area of the second substrate 112. One area of the second substrate 112 may be an area in which the first pad connection line 161 or the third pad connection line 163 is disposed, and the other area of the second substrate 112 may be an area in which the second pad connection line 162 or the fourth pad connection line 164 is disposed.

The first pad 165 and the second pad 166 may be connected to a plurality of pad connection lines 161, 162, 163, and 164. Specifically, the first pad 165 may be connected to at least one first pad connection line 161 and at least one third pad connection line 163, and the second pad 166 may be connected to at least one second pad connection line 162 and at least one fourth pad connection line 164.

The first pad 165 and the second pad 166 may be directly connected to the plurality of TSVs 170. Specifically, the first pad 165 may be directly connected to the first TSV 171 connected to the first metal pattern 143 and the third TSV 173 connected to the third metal pattern 145. The second pad 166 may be directly connected to the second TSV 172 connected to the second metal pattern 144 and the fourth TSV 174 connected to the fourth metal pattern 146. Since the first pad 165 and the second pad 166 are directly connected to the first metal layer 141 and the second metal layer 142 through the plurality of TSVs 170, a connection distance between the first and second pads 165 and 166 and the first and second trench capacitors 121 and 122 can be reduced. Accordingly, parasitic effects in a connection line between the first and second pads 165 and 166 and the first and second trench capacitors 121 and 122 can be reduced, and the integration density of the capacitor 100 can be improved.

Referring to FIG. 2, the TSV 170 may be disposed to pass through the second substrate 112. Specifically, the plurality of TSVs 170 may be disposed to pass through the second substrate 112 between the metal pad layer 160 and the first metal layer 141 or between the metal pad layer 160 and the second metal layer 142. More specifically, the plurality of TSVs 170 may be disposed to vertically pass through openings of the second substrate 112 and the second trench capacitor 122 between the metal pad layer 160 and the first metal layer 141 or between the metal pad layer 160 and the second metal layer 142.

The plurality of TSVs 170 may include the first TSV 171, the second TSV 172, the third TSV 173, and the fourth TSV 174. Specifically, the plurality of TSVs 170 may include the first TSV 171 connected to the first metal pattern 143, the second TSV 172 connected to the second metal pattern 144, the third TSV 173 connected to the third metal pattern 145, and the fourth TSV 174 connected to the fourth metal pattern 146. For example, the first TSV 171 may be disposed between the metal pad layer 160 and the first metal pattern 143, the second TSV 172 may be disposed between the metal pad layer 160 and the second metal pattern 144, the third TSV 173 may be disposed between the metal pad layer 160 and the third metal pattern 145, and the fourth TSV 174 may be disposed between the metal pad layer 160 and the fourth metal pattern 146. Since a plurality of metal patterns 143, 144, 145, and 146 are directly connected to different TSVs 171, 172, 173, and 174, the plurality of metal patterns 143, 144, 145, and 146 may be connected to the metal pad layer 160 at the shortest distance. In addition, the metal pad layer 160 may be vertically connected to the trench capacitors 121 and 122 through a plurality of TSVs 171, 172, 173, and 174 and the metal patterns 143, 144, 145, and 146 in an area overlapping the trench capacitors 121 and 122. Accordingly, since a connection distance between the trench capacitors 121 and 122 and the pads 165 and 166 is reduced and a contact portion is increased, the ESR between the trench capacitors 121 and 122 and the pads 165 and 166 can be improved.

The second trench capacitor 122 according to the present embodiment includes the plurality of openings so that the plurality of TSVs 170 may be directly disposed in a capacitor design area of the first substrate 111 and the second substrate 112. Accordingly, by directly connecting the plurality of TSVs 170 to the plurality of first to fourth metal patterns 143, 144, 145, and 146, a contact path from a front surface of each of the first and second trench capacitors 121 and 122 to the metal pad layer 160 can be uniformly distributed, and a contact area can be increased. Accordingly, a length of a connection line between the first and second trench capacitors 121 and 122 and the first and second pads 165 and 166 is reduced, and the uniformity of a contact path, the density of contact holes, and a contact area are increased, thereby improving the ESR of the capacitor 100.

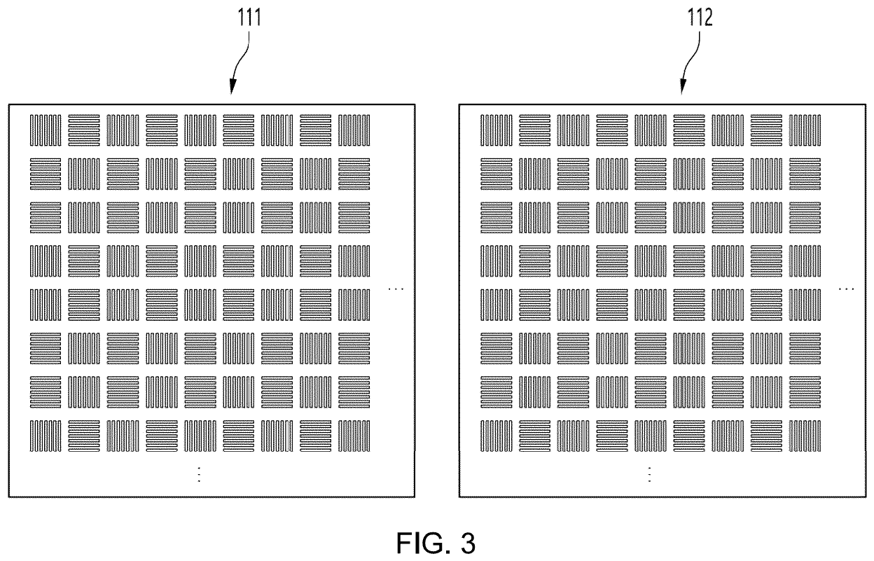

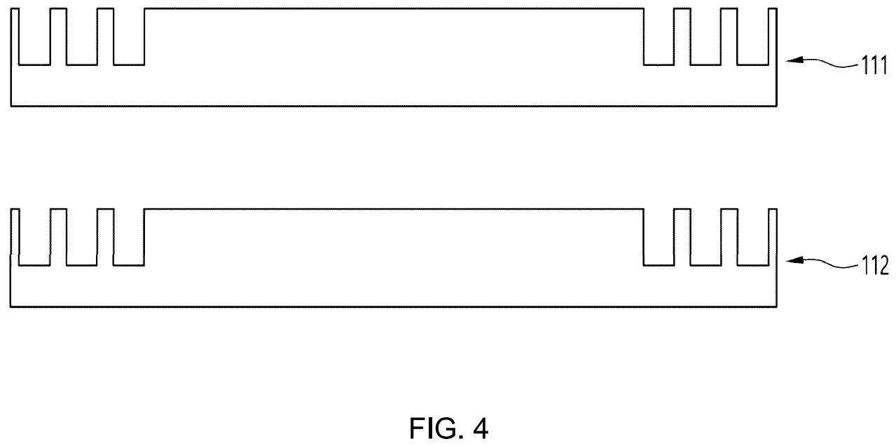

FIG. 3 is a top view for describing a method of forming grooves in a first substrate and a second substrate of a capacitor according to one embodiment of the present disclosure. FIG. 4 is a cross-sectional view for describing the method of forming grooves in a first substrate and a second substrate of FIG. 3.

Referring to FIG. 3, grooves may be formed in each of the upper surface of the first substrate 111 and one surface of the second substrate 112. A structural layout of the grooves of the first substrate 111 may be the same as a structural layout of the grooves of the second substrate 112. Specifically, the grooves of the first substrate 111 and the grooves of the second substrate 112 may be formed at the same position, at the same interval, and in the same number. Accordingly, the grooves of the first substrate 111 and the grooves of the second substrate 112 are formed through the same process, thereby improving a process efficiency of the capacitor 100 and reducing a cost and time required for manufacturing.

Referring to FIG. 4, a plurality of grooves may be formed in each of the upper surface of the first substrate 111 and one surface of the second substrate 112. Specifically, a photolithography process apparatus and an etching process apparatus may simultaneously form the plurality of grooves in each of the upper surface of the first substrate 111 and one surface of the second substrate 112. Accordingly, even when slight process errors occur during a photolithography process and an etching process, process errors may occur simultaneously in the first substrate 111 and the second substrate 112 so that the plurality of grooves of the first substrate 111 and the plurality of grooves of the second substrate 112 may be formed in a similar manner. In addition, a process for the first substrate 111 and a process for the second substrate 112 are performed simultaneously, thereby simplifying a manufacturing operation of the capacitor 100 and reducing a cost and time required for manufacturing. In some cases, the photolithography process apparatus and the etching process apparatus may each perform the process for the first substrate 111 and the process for the second substrate 112 under the same process variables.

According to various embodiments of the present disclosure, the groove of the first substrate 111 and the groove of the second substrate 112 may be formed in different shapes. For example, one groove of the second substrate 112 may be formed to be longer than the groove of the first substrate 111. In the present embodiment, a description will be provided based on an example in which the groove of the first substrate 111 and the groove of the second substrate 112 are formed in the same shape.

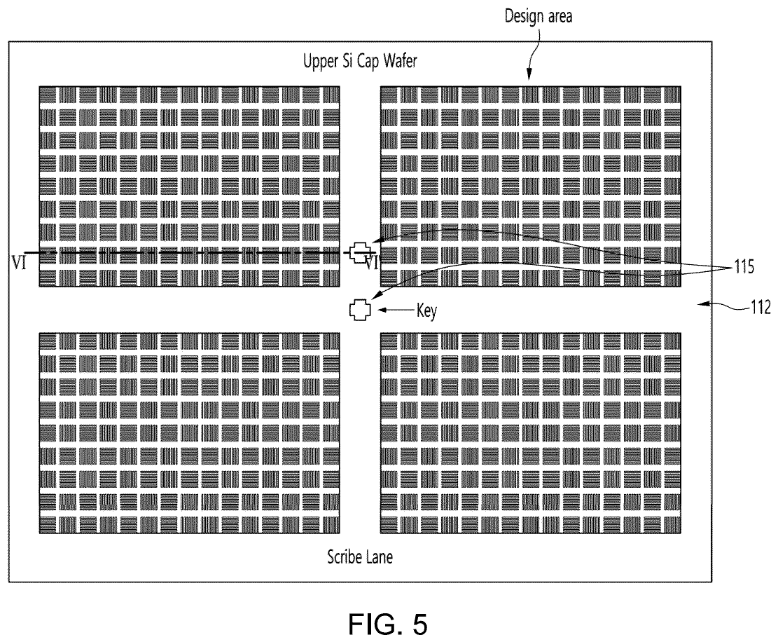

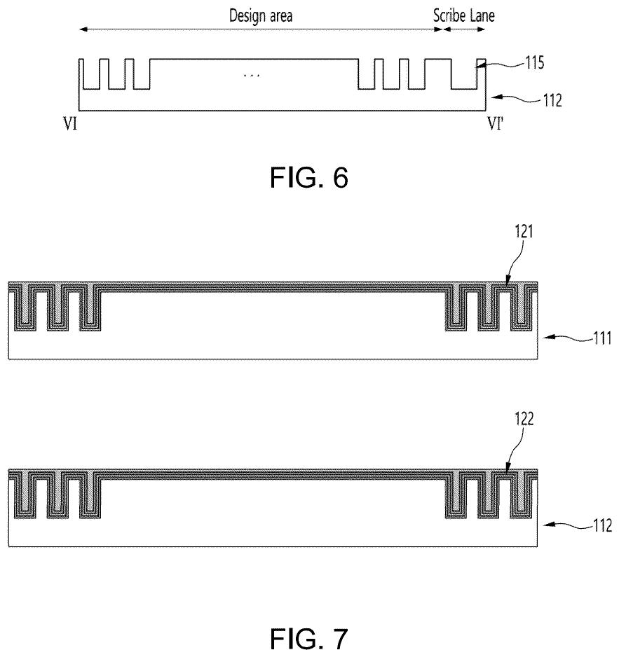

FIG. 5 is a top view for describing a method of manufacturing an alignment key on a second substrate of a capacitor according to one embodiment of the present disclosure. FIG. 6 is a cross-sectional view of the second substrate of FIG. 5 along line VI-VI′.

Referring to FIGS. 5 and 6, grooves may be formed in a scribe lane of the second substrate 112. Specifically, at least one alignment key 115 may be patterned in a scribe lane of one surface of the second substrate 112. The alignment key 115 may be formed through the same process as grooves formed in a capacitor design area of the second substrate 112. That is, the photolithography process apparatus and the etching process apparatus may simultaneously form at least one alignment key 115 in the scribe lane of the second substrate 112 and a plurality of grooves of the second substrate 112. Accordingly, a manufacturing process of the capacitor 100 can be simplified by forming the alignment key 115 without adding a separate manufacturing process or changing process variables. That is, by forming the alignment key 115 and the grooves of the second substrate 112 through the same process, a separate manufacturing process of forming the alignment key 115 can be omitted, and a manufacturing cost and time can be reduced.

The alignment key 115 may have a different shape from the groove of the second substrate 112. Specifically, the alignment key 115 may be formed with a different length and a different width from the groove of the second substrate 112. For example, as shown in FIG. 5, the alignment key 115 may be formed in a cross shape having a greater width and greater length than the groove of the second substrate 112. In some cases, the alignment key 115 may be formed to the same depth as the groove of the second substrate 112. Accordingly, the alignment key 115 may be formed through the same process as the groove of the second substrate 112. Specifically, the photolithography process apparatus and the etching process apparatus may simultaneously pattern the alignment key 115 and trenches of the second substrate 112 through openings of a mask having different sizes in the same process without changing process variables such as an air pressure and an etching time in a chamber, and the characteristics of an etching composition.

According to various embodiments of the present disclosure, an alignment key (not shown) may be disposed in the capacitor design area of the second substrate 112. Specifically, at least one of a plurality of trenches disposed in the capacitor design area of the second substrate 112 may have a relatively great width or a relatively great length. For example, any one of vertical trench units that is farthest from the alignment key 115 disposed in the scribe lane may include at least one trench having a relatively great vertical length. In some cases, each of a plurality of capacitor design areas disposed on a wafer may include at least one vertical trench unit including at least one trench having a relatively great vertical length or a relatively wider horizontal width. The area c and area d of the second trench capacitor 122 may have a relatively greater width than the area a and area b so that a trench of the vertical trench unit may be formed to have a relatively great vertical length. In addition, even when the trench of the vertical trench unit has a relatively great vertical length, it is possible to prevent parasitic effects that may occur due to proximity to horizontal trench units disposed on and below the vertical trench unit and a problem of degradation in mechanical stability of the second substrate 112.

FIG. 7 is a cross-sectional view illustrating a method of manufacturing a first trench capacitor and a second trench capacitor according to one embodiment of the present disclosure.

Referring to FIG. 7, the first trench capacitor 121 may be formed on one surface of the first substrate 111, and the second trench capacitor 122 may be formed on one surface of the second substrate 112. Specifically, a deposition process apparatus may form the first trench capacitor 121 on an upper surface in which grooves of the first substrate 111 are disposed and may form the second trench capacitor 122 on one surface in which grooves of the second substrate 112 are disposed. More specifically, the deposition process apparatus may sequentially deposit the first electrode, the first insulating layer, the second electrode, the second insulating layer, the third electrode, the third insulating layer, and the fourth electrode on each of the first substrate 111 and the second substrate 112. The deposition process apparatus may be any one of an atomic layer deposition (ALD) apparatus, a chemical vapor deposition (CVD) apparatus, a physical vapor deposition (PVD) apparatus, a sputtering apparatus, and an electroplating apparatus. Preferably, the deposition process apparatus may be the CVD apparatus. Accordingly, the first electrode, the first insulating layer, the second electrode, the second insulating layer, the third electrode, the third insulating layer, and the fourth electrode of each of the first and second trench capacitors 121 and 122 may be formed to have a uniform thickness on inner sidewalls and upper surfaces of each of trenches of each of the first and second substrates 111 and 112. In some cases, the fourth electrode may be formed to fill a space remaining on the third insulating layer within the trench of each of the first substrate 111 and the second substrate 112.

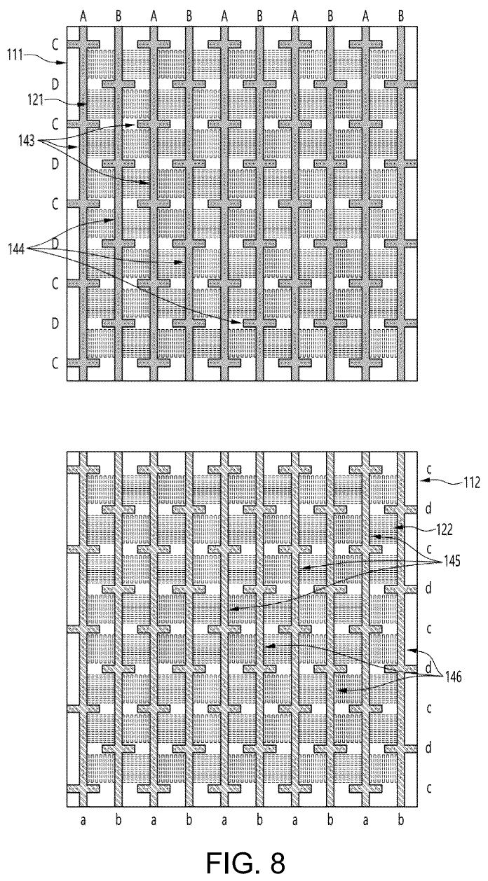

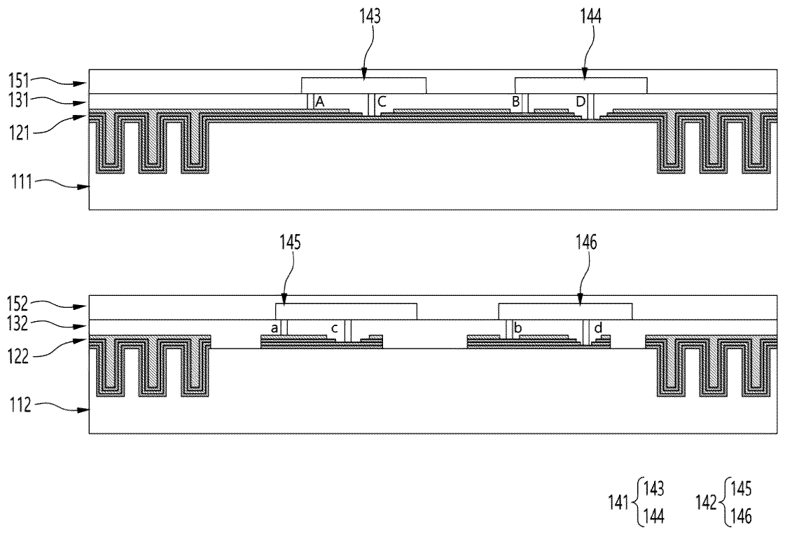

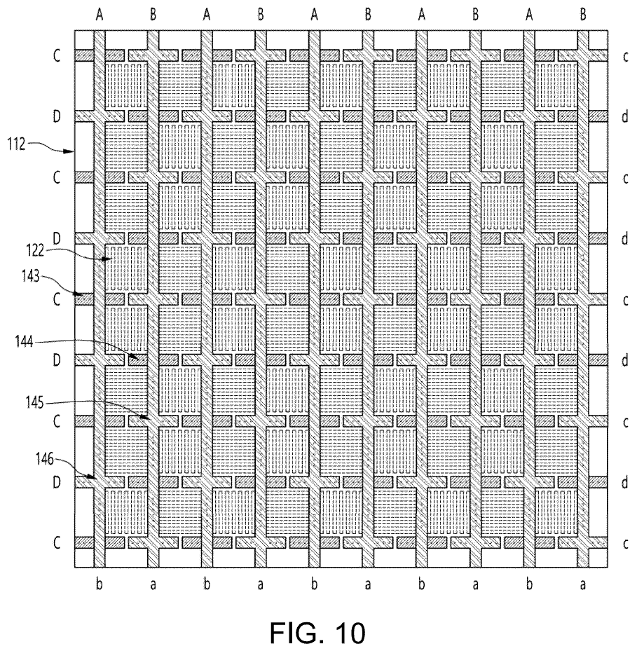

FIG. 8 is a top view for describing a method of manufacturing a first metal layer and a second metal layer of a capacitor according to one embodiment of the present disclosure. FIG. 9 is a cross-sectional view for describing the method of manufacturing a first metal layer and a second metal layer of FIG. 8.

Referring to FIG. 9, a plurality of openings may be formed in the second trench capacitor 122. Specifically, the photolithography process apparatus and the etching process apparatus may etch portions of the second trench capacitor 122 to form the openings passing through the second trench capacitor 122.

In a process of forming the openings, the second trench capacitor 122 may be etched using the alignment key 115. Specifically, positions at which the plurality of openings of the second trench capacitor 122 are formed may be determined based on the alignment key 115. For example, a vision camera may sense the alignment key 115, and an alignment module may determine the positions, at which the plurality of openings are formed, based on the position of the alignment key 115 and may align a mask at the determined positions at which the plurality of openings are formed. The photolithography process apparatus and the etching process apparatus may form the openings passing through the second trench capacitor 122 by patterning a photoresist at a position determined through the aligned mask and etching the second trench capacitor 122. The vision camera and the alignment module may be disposed in each semiconductor process apparatus or may be an independent device separate from the semiconductor process apparatus. Preferably, the vision camera and the alignment module may be included in each of the photolithography process apparatus and an etching apparatus. Since a process of forming the plurality of openings includes a process of aligning the mask through the alignment key 115, the plurality of openings may be formed more accurately at pre-designed positions. In addition, even when some slight process errors occur in mask alignment during a formation operation of a plurality of trenches, since the same process error also occurs in the alignment key 115 formed through the same process as the plurality of trenches, by forming the plurality of openings based on the alignment key 115, the plurality of openings may be formed at positions at which the process errors of the plurality of trenches are reflected. That is, the photolithography process apparatus and the etching process apparatus etch the second trench capacitor 122 and form the plurality of openings by using the alignment key 115, thereby improving the consistency of positions of the plurality of trenches and the plurality of openings and minimizing the influence of process errors.

Referring to FIG. 8, each of the first and second trench capacitors 121 and 122 may have contact holes in which the first electrode, the second electrode, the third electrode, and the fourth electrode are exposed. For example, when an insulating layer is disposed on an upper surface of the fourth electrode, the photolithography process apparatus and the etching process apparatus may etch a partial area of the insulating layer disposed on the upper surface of the fourth electrode of the area A, thereby forming the A contact hole in which the fourth electrode is exposed. In some cases, when an A contact hole formation process is performed, at the same time the photolithography process apparatus and the etching process apparatus may expose the fourth electrode by etching a partial area of the insulating layer disposed on the fourth electrode of each of a partial area of the area B, a partial area of the area C, and a partial area of the area D. The photolithography process apparatus and the etching process apparatus may etch the fourth electrode and the third insulating layer exposed in a partial area of the area B, a partial area of the area C, and a partial area of the area D, thereby forming the B contact hole in which the third electrode is exposed and exposing the third electrode in a partial area of the area C and a partial area of the area D. The photolithography process apparatus and the etching process apparatus may etch the third electrode and the second insulating layer exposed in a partial area of the area C and a partial area of the area D, thereby forming the C contact hole in which the second electrode is exposed in the area C and exposing the second electrode in the area D. The photolithography process apparatus and the etching process apparatus may etch the second electrode and the first insulating layer exposed in a partial area of the area D, thereby forming the D contact hole in which the first electrode is exposed in the area D.

Widths of the C contact hole, the D contact hole, the c contact hole, and the d contact hole may be greater than widths of the B contact hole and the b contact hole. Specifically, in order to further etch the first insulating layer, the second electrode, the second insulating layer, the third electrode, or the third insulating layer, the photolithography process apparatus and the etching process may perform etching such that an etching area of the first electrode in the C contact hole, the D contact hole, the c contact hole, and the d contact hole is greater that an etching area of the first electrode in the B contact hole and the b contact hole. Accordingly, widths of the area C, the area D, the area c, and the area d are formed to be greater than widths of the area a, the area A, the area B, and the area b to form the C contact hole, the D contact hole, the c contact hole, and the d contact hole to have a greater width, thereby preventing problems that may occur due to process errors.

Referring to FIG. 9, the first dielectric layer 131 may be formed on the first trench capacitor 121, and the second dielectric layer 132 may be formed on the second trench capacitor 122. Specifically, the deposition process apparatus may deposit the first dielectric layer 131 on the first trench capacitor 121 and may deposit the second dielectric layer 132 on the second trench capacitor 122.

Referring to FIGS. 8 and 9, the plurality of first through-holes may be formed in each of the first dielectric layer 131 and the second dielectric layer 132. Specifically, the photolithography process apparatus and the etching process apparatus may form the first A through-hole passing through the first dielectric layer 131 and connected to the fourth electrode of the first trench capacitor 121, the first B through-hole connected to the third electrode of the first trench capacitor 121, the first C through-hole connected to the second electrode of the first trench capacitor 121, the first D through-hole connected to the first electrode of the first trench capacitor 121, the first a through-hole passing through the second dielectric layer 132 and connected to the fourth electrode of the second trench capacitor 122, the first b through-hole connected to the third electrode of the second trench capacitor 122, the first c through-hole connected to the second electrode of the second trench capacitor 122, and the first d through-hole connected to the first electrode of the second trench capacitor 122.

A conductive material may be formed within the plurality of first through-holes. Specifically, the deposition process apparatus may form a conductive material within the first through-holes formed in the first dielectric layer 131 and the second dielectric layer 132. Accordingly, the plurality of first through-holes may be conductive vias that may electrically connect the first trench capacitor 121 to the first metal layer 141 and may electrically connect the second trench capacitor 122 to the second metal layer 142.

Referring to FIGS. 8 and 9, the first metal layer 141 may be formed on the first dielectric layer 131 to cover the first through-hole and connect to the first trench capacitor, and the second metal layer 142 may be formed on the second dielectric layer 132 to cover the first through-hole and connect to the second trench capacitor. Specifically, the deposition process apparatus may form a metal layer on the first dielectric layer 131 and the second dielectric layer 132, and the photolithography process apparatus and the etching process apparatus etch the metal layer disposed on the first dielectric layer 131 and the second dielectric layer 132, thereby patterning each of the first metal layer 141 and the second metal layer 142. More specifically, the photolithography process apparatus and the etching process apparatus may form the first metal pattern 143 connected to the first A through-hole and the first C through-hole of the first dielectric layer 131, the second metal pattern 144 connected to the first B through-hole and the first D through-hole of the first dielectric layer 131, the third metal pattern 145 connected to the first a through-hole and the first c through-hole of the second dielectric layer 132, and the fourth metal pattern 146 connected to the first b through-hole and the first d through-hole of the second dielectric layer 132. For example, as shown in FIG. 8, the long pattern portion of the first metal pattern 143 disposed to overlap the area A of the first trench capacitor 121 may be formed to be connected to the first A through-hole, and the short pattern portion of the first metal pattern 143 disposed to overlap the area C of the first trench capacitor 121 may be formed to be connected to the first C through-hole.

Referring to FIG. 9, the third dielectric layer 151 may be formed to cover the first metal layer 141 on the first dielectric layer 131, and the fourth dielectric layer 152 may be formed to cover the second metal layer 142 on the second dielectric layer 132. Specifically, the deposition process apparatus may deposit the third dielectric layer 151 on the first dielectric layer 131 and the first metal layer 141 and may deposit the fourth dielectric layer 152 on the second dielectric layer 132 and the second metal layer 142.

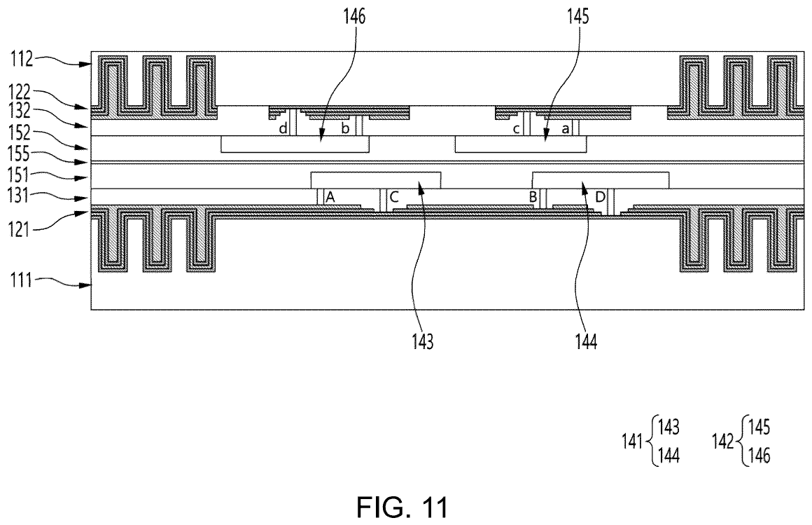

FIG. 10 is a top view for describing a method of bonding a first substrate and a second substrate of a capacitor according to one embodiment of the present disclosure. FIG. 11 is a cross-sectional view for describing the method of bonding a first substrate and a second substrate of FIG. 10.

Referring to FIGS. 10 and 11, the first substrate 111 and the second substrate 112 may be bonded in the direction perpendicular to the first substrate 111. Specifically, the third dielectric layer 151 and the fourth dielectric layer 152 may be bonded such that the upper surface of the first substrate 111 and one surface of the second substrate 112 face each other. That is, as shown in FIG. 11, an upper surface of the third dielectric layer 151 on the first substrate 111 and an upper surface of the fourth dielectric layer 152 on the second substrate 112 may be bonded to each other at the bonding layer 155. For example, the third dielectric layer 151 and the fourth dielectric layer 152 may be bonded at the bonding layer 155 through any one of adhesive bonding, oxide bonding, and fusion bonding.

When the third dielectric layer 151 and the fourth dielectric layer 152 are bonded through adhesive bonding, the bonding layer 155 may include an adhesive. Specifically, an adhesive layer may be disposed on the third dielectric layer 151, and the first substrate 111 and the second substrate 112 may be bonded to each other such that the fourth dielectric layer 152 is located on the adhesive layer. That is, the bonding layer 155 may be applied as an adhesive on the upper surface of the third dielectric layer 151, and the upper surface of the fourth dielectric layer may be bonded onto the applied bonding layer 155. In some cases, the third dielectric layer 151 and the fourth dielectric layer 152 may be bonded through oxide bonding. Specifically, the fourth dielectric layer 152 may be disposed in close contact with the upper surface of the third dielectric layer 151, and chemical bonding may be performed through a low-temperature annealing process.

Referring to FIGS. 10 and 11, a portion of the first metal layer 141 and a portion of the second metal layer 142 may overlap each other in the direction perpendicular to the first substrate 111. Specifically, in a plane view of the first substrate 111, the long pattern portion of the first metal layer 141 and the long pattern portion of the second metal layer 142 may overlap each other, and at least a portion of the short pattern portion of the first metal layer 141 and at least a portion of the short pattern portion of the second metal layer 142 may not overlap each other. Accordingly, at least a portion of the short pattern portion of the first metal layer 141 may secure a contact area that does not overlap the second metal layer 142. In addition, the short pattern portion of the first metal layer 141 may be disposed to overlap the area C and the area D of the first trench capacitor 121 and thus may be formed to have a width that is greater than a width of the long pattern portion formed to be relatively narrow. Therefore, the first metal layer 141 may secure a sufficient contact area to be connected to the TSV 170.

Referring to FIG. 11, the second substrate 112 bonded to the first substrate 111 may be thinned. Specifically, a thickness of the second substrate 112 may be reduced from the other surface located opposite to one surface of the second substrate 112 on which the second trench capacitor 122 is disposed. That is, a thinning process apparatus may reduce the thickness of the second substrate 112 from the upper surface of the second substrate 112 bonded to the first substrate 111. The thinning process apparatus may include any one of a chemical mechanical polishing (CMP) apparatus, a mechanical polishing apparatus, and a wet or dry etching apparatus. By thinning the second substrate 112, a plurality of grooves of the second trench capacitor 122 disposed in the second substrate 112 or the alignment key 115 disposed in the scribe lane of the second substrate 112 may be sensed on the upper surface of the second substrate 112.

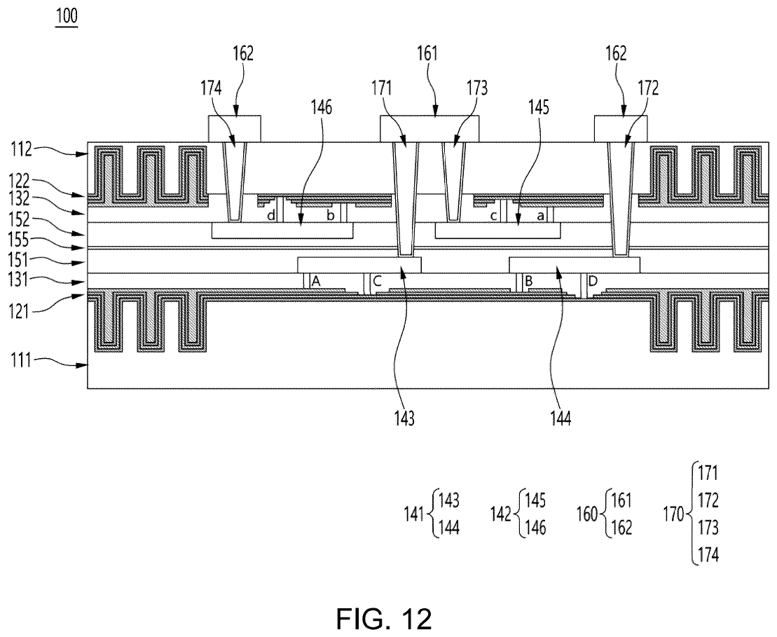

FIG. 12 is a cross-sectional view for describing a method of manufacturing a plurality of TSVs and a metal pad layer of a capacitor according to one embodiment of the present disclosure.

Referring to FIG. 12, the plurality of TSVs 170 passing through the second substrate 112 may be formed. Specifically, the photolithography process apparatus and the etching process apparatus may pattern a photoresist to determine arrangement positions and sizes of the plurality of TSVs 170, and a drilling process apparatus or the etching process apparatus may form holes passing through the second substrate 112 at a position at which the photoresist is patterned. The deposition process apparatus may form the TSV 170 by depositing a conductive material inside the holes passing through the second substrate 112.

A vision camera of the photolithography process apparatus may sense a position of the alignment key 115 disposed in the scribe lane on the upper surface of the second substrate 112, and the alignment module may recognize positions, at which a plurality of openings are formed, based on the position of the sensed alignment key 115 and may determine the position at which the photoresist is patterned. The drilling process apparatus or the etching process apparatus may form the plurality of TSVs 170 at the positions at which the plurality of openings are formed. Specifically, the drilling process apparatus or the etching process apparatus may form the holes passing through the second substrate 112 at the positions at which the plurality of openings are formed, and the deposition process apparatus may form the TSV 170 by depositing a conductive material inside the holes passing through the second substrate 112.

In some cases, the vision camera of the photolithography process apparatus may sense the second trench capacitor 122 on the upper surface of the second substrate 112. Specifically, the vision camera may sense positions of a plurality of grooves of the second trench capacitor 122 and a position of the alignment key 115 disposed in a capacitor design area. The alignment module may recognize the positions, at which the plurality of openings are formed, based on the sensed position of the second trench capacitor 122. Specifically, the alignment module may recognize the positions, at which the plurality of openings are formed, based on the plurality of grooves of the sensed second trench capacitor 122 and the position of the alignment key 115 disposed in the capacitor design area and may determine the position at which the photoresist is patterned. The drilling process apparatus or the etching process apparatus may form the plurality of TSVs 170 at the positions at which the plurality of openings are formed. Specifically, the drilling process apparatus or the etching process apparatus may form the holes passing through the second substrate 112 at the positions at which the plurality of openings are formed, and the deposition process apparatus may form the TSV 170 by depositing a conductive material inside the holes passing through the second substrate 112.

Referring to FIG. 12, the metal pad layer 160 connected to the plurality of TSVs 170 may be formed on the other surface of the second substrate 112. Specifically, the deposition process apparatus may deposit a metal layer to cover the plurality of TSVs 170 on the upper surface of the second substrate 112, and the photolithography process apparatus and the etching process apparatus may form the metal pad layer 160 by patterning a conductive layer disposed on the upper surface of the second substrate 112.

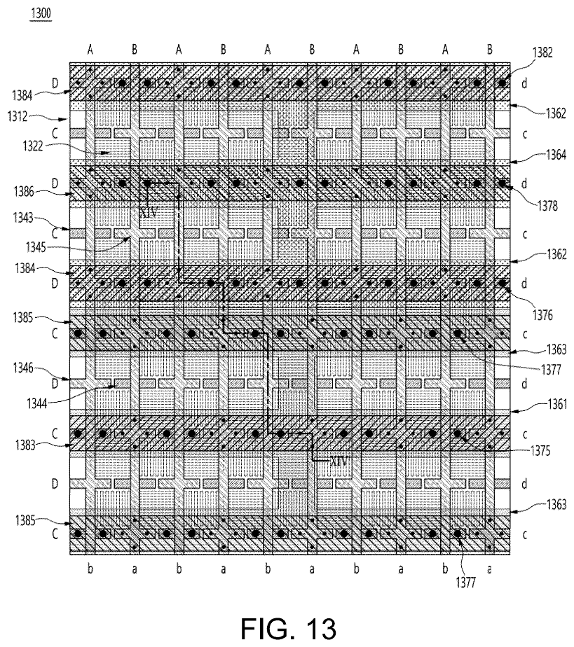

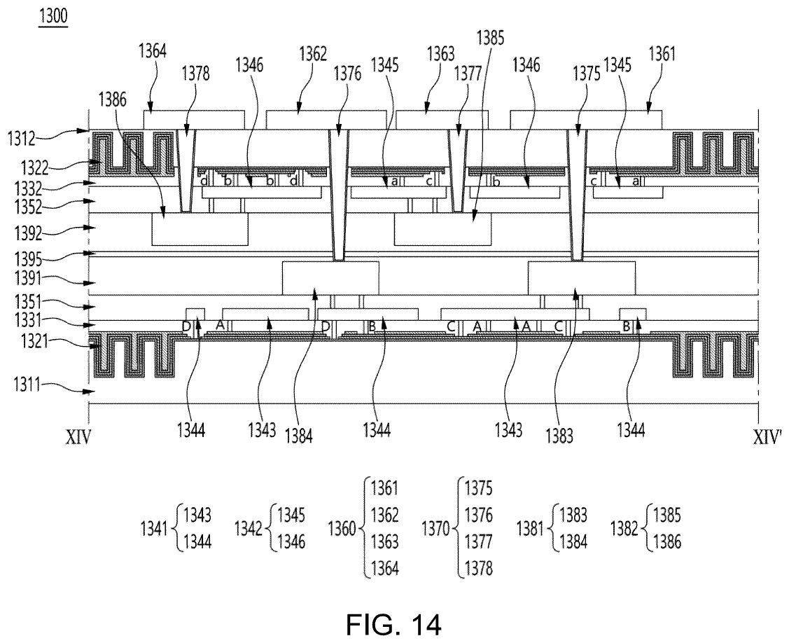

FIG. 13 is a top view of a capacitor according to another embodiment of the present disclosure. FIG. 14 is a cross-sectional view of the capacitor of FIG. 13 along line XIV-XIV′.

Referring to FIGS. 13 and 14, a capacitor 1300 according to the present embodiment may further include a third metal layer 1381, a fourth metal layer 1382, a fifth dielectric layer 1391, and a sixth dielectric layer 1392 in the configuration of the capacitor 100 of FIG. 1. A bonding layer 1395 may be disposed between the fifth dielectric layer 1391 and the sixth dielectric layer 1392, and a plurality of TSVs 1370 may be disposed between a metal pad layer 1380 and any one of the third metal layer 1381 and the fourth metal layer 1382. Accordingly, a redundant description of components that are substantially the same as those of the capacitor 100 of FIG. 1 will be omitted.

Referring to FIG. 14, the third metal layer 1381 may be disposed on an upper surface of a third dielectric layer 1351, and the fourth metal layer 1382 may be disposed on one surface of a fourth dielectric layer 1352. Specifically, the third metal layer 1381 may be disposed on the upper surface of the third dielectric layer 1351 facing a second substrate 1312, and the fourth metal layer 1382 may be disposed on one surface of the fourth dielectric layer 1352 facing a first substrate 1311. That is, as shown in FIG. 14, the third metal layer 1381 may be directly disposed on the third dielectric layer 1351, the fourth metal layer 1382 may be disposed on the third metal layer 1381, and the fourth dielectric layer 1352 may be directly disposed on the fourth metal layer 1382.

The third metal layer 1381 may include fifth metal patterns 1383 and sixth metal patterns 1384. Specifically, the third metal layer 1381 may include a plurality of fifth metal patterns 1383 and a plurality of sixth metal patterns 1384 which are spaced apart from each other.

The fourth metal layer 1382 may include seventh metal patterns 1385 and eighth metal patterns 1386. Specifically, the fourth metal layer 1382 may include a plurality of seventh metal patterns 1385 and a plurality of eighth metal patterns 1386 which are disposed to be spaced apart from each other.

The third metal layer 1381 may be connected to a first metal layer 1341, and the fourth metal layer 1382 may be connected to a second metal layer 1342. The first metal layer 1341 and the second metal layer 1342 may be substantially the same as the first metal layer 141 and the second metal layer 142 of FIGS. 1 and 2. The third metal layer 1381 may include a fifth metal pattern 1383 connected to a first metal pattern 1343 and a sixth metal pattern 1384 connected to a second metal pattern 1344, and the fourth metal layer 1382 may include the seventh metal pattern 1385 connected to a third metal pattern 1345 and the eighth metal pattern 1386 connected to a fourth metal pattern 1346.

The fifth metal pattern 1383, the sixth metal pattern 1384, the seventh metal pattern 1385, and the eighth metal pattern 1386 may have various shapes. For example, as shown in FIG. 13, the fifth to eighth metal patterns 1383, 1384, 1385, and 1386 may have a shape extending in a horizontal direction in a plane view of the second substrate 1312. That is, the fifth to eighth metal patterns 1383, 1384, 1385, and 1386 may extend in a longitudinal direction of short pattern portions of the first to fourth metal patterns 1343, 1344, 1345, and 1346 and may have a width that is greater than a vertical width of the short pattern portions of the first to fourth metal patterns 1343, 1344, 1345, and 1346. Accordingly, each of the fifth to eighth metal patterns 1383, 1384, 1385, and 1386 overlaps both the first metal layer 1341 and the second metal layer 1342 in a direction perpendicular to the first substrate 1311, thereby securing a contact area with both the first metal layer 1341 and the second metal layer 1342.

Referring to FIG. 13, the plurality of fifth metal patterns 1383 and the plurality of sixth metal patterns 1384 may be arranged to be coplanar in one direction. Specifically, a plurality of fifth metal patterns 1383 and a plurality of sixth metal patterns 1384 extending in a horizontal direction on a plane view of the first substrate 1311 may be arranged in a vertical direction. For example, as shown in FIG. 13, the plurality of fifth metal patterns 1383 may be disposed in areas C at both sides which are closest to a corresponding area C in one area of the first substrate 1311 with one area C interposed therebetween, and the plurality of sixth metal patterns 1384 may be disposed in areas D at both sides which are closest to a corresponding area D in the other area of the first substrate 1311 with one area D interposed therebetween. In addition, the plurality of seventh metal patterns 1385 may be disposed in areas c at both sides which are closest to a corresponding area c in one area of the second substrate 1312 with one area c interposed therebetween, and the plurality of eighth metal patterns 1386 may be disposed in areas d at both sides which are closest to a corresponding area d in the other area of the second substrate 1312 with one area d interposed therebetween. The plurality of fifth metal patterns 1383, the plurality of sixth metal patterns 1384, the plurality of seventh metal patterns 1385, and the plurality of eighth metal patterns 1386 may not overlap each other in the direction perpendicular to the first substrate 1311. Accordingly, each of the fifth to eighth metal patterns 1383, 1384, 1385, and 1386 overlaps both the first metal layer 1341 and the second metal layer 1342 in the direction perpendicular to the first substrate 1311, thereby securing a contact area with each of the first metal layer 1341 and the second metal layer 1342. In addition, one area of the first substrate 1311 in which the plurality of fifth metal patterns 1383 are disposed and one area of the second substrate 1312 in which the plurality of seventh metal patterns 1385 are disposed may be disposed to overlap each other in the direction perpendicular to the first substrate 1311 so that the plurality of fifth metal patterns 1383 and the plurality of seventh metal patterns 1385 may be connected to each other through a vertical pad connection line of a metal pad layer 1360.

Referring to FIG. 14, second through-holes may be disposed in each of the third dielectric layer 1351 and the fourth dielectric layer 1352. Specifically, the second through-holes may be disposed between the first metal layer 1341 and the third metal layer 1381 and between the second metal layer 1342 and the fourth metal layer 1382. More specifically, the second through-holes may be disposed between the first metal pattern 1343 and the fifth metal pattern 1383, between the second metal pattern 1344 and the sixth metal pattern 1384, between the third metal pattern 1345 and the seventh metal pattern 1385, and between the fourth metal pattern 1346 and the eighth metal pattern 1386.

A conductive material may be disposed within the plurality of second through-holes. Accordingly, the plurality of second through-holes may be conductive vias that may electrically connect the first metal layer 1341 and the third metal layer 1381 and may electrically connect the second metal layer 1342 and the fourth metal layer 1382.

Referring to FIG. 14, the fifth dielectric layer 1391 may be disposed to cover the third metal layer 1381, and the sixth dielectric layer 1392 may be disposed to cover the fourth metal layer 1382. Specifically, the fifth dielectric layer 1391 and the sixth dielectric layer 1392 may be disposed between the third metal layer 1381 and the fourth metal layer 1382 to cover the third metal layer 1381 and the fourth metal layer 1382, respectively. That is, as shown in FIG. 14, the fifth dielectric layer 1391 may be disposed on the third metal layer 1381, the sixth dielectric layer 1392 may be disposed on the fifth dielectric layer 1391, and the fourth metal layer 1382 may be disposed on the sixth dielectric layer 1392.

The fifth dielectric layer 1391 and the sixth dielectric layer 1392 may be insulating layers that are substantially the same as a first dielectric layer 1331 and a second dielectric layer 1332. For example, the fifth dielectric layer 1391 and the sixth dielectric layer 1392 may include SiO₂, Si₃N₄, SiOₓN_{y}, or a low-k material.

The fifth dielectric layer 1391 and the sixth dielectric layer 1392 may be bonded at the bonding layer 1395. The bonding layer 1395 may be substantially the same as the bonding layer 155 of FIG. 2. That is, the bonding layer 1395 may include an adhesive such as a resin adhesive such as an epoxy resin or an acrylic resin, polyimide, or a silicone adhesive or may include the same material as the fifth dielectric layer 1391 and the sixth dielectric layer 1392.

Referring to FIGS. 13 and 14, the metal pad layer 1360 may be disposed on the other surface opposite to one surface of the second substrate 1312 on which a second trench capacitor 1322 is disposed. The shape and layout of the metal pad layer 1360 may be substantially the same as the shape and layout of the metal pad layer 160 of FIG. 1.

The metal pad layer 1360 may include a plurality of pad connection lines. Specifically, the metal pad layer 1360 may include a first pad connection line 1361, a second pad connection line 1362, a third pad connection line 1363, and a fourth pad connection line 1364. In some cases, the metal pad layer 1360 may further include a fifth pad connection line 1365, a sixth pad connection line 1366, a first pad 1367, and a second pad 1368.

Referring to FIG. 13, the first to fourth pad connection lines 1361, 1362, 1363, and 1364 may extend in a longitudinal direction of the third metal layer 1381 and the fourth metal layer 1382 and may be disposed to overlap any one of the third metal layer 1381 and the fourth metal layer 1382. For example, in a direction perpendicular to the second substrate 1312, the first pad connection line 1361 may be disposed to overlap the fifth metal pattern 1383, the second pad connection line 1362 may be disposed to overlap the sixth metal pattern 1384, the third pad connection line 1363 may be disposed to overlap the seventh metal pattern 1385, and the fourth pad connection line 1364 may be disposed to overlap the eighth metal pattern 1386.

Referring to FIG. 14, the first to fourth pad connection lines 1361, 1362, 1363, and 1364 may be connected to the third metal layer 1381 and the fourth metal layer 1382. Specifically, the first to fourth pad connection lines 1361, 1362, 1363, and 1364 may be directly connected to the third metal layer 1381 and the fourth metal layer 1382 through the plurality of TSVs 1370. For example, the first pad connection line 1361 may be connected to the fifth metal pattern 1383 through a fifth TSV 1375, the second pad connection line 1362 may be connected to the sixth metal pattern 1384 through a sixth TSV 1376, the third pad connection line 1363 may be connected to the seventh metal pattern 1385 through a seventh TSV 1377, and the fourth pad connection line 1364 may be connected to the eighth metal pattern 1386 through an eighth TSV 1378.

The fifth pad connection line 1365 and the sixth pad connection line 1366 may have substantially the same layout and connection relationship as the third pad connection line 163 and the fourth pad connection line 164 of FIG. 1. That is, the fifth pad connection line 1365 and the sixth pad connection line 1366 extend in a direction perpendicular to a direction in which the first to fourth pad connection lines 1361, 1362, 1363, and 1364 extend, the fifth pad connection line 1365 may be connected to the first pad connection line 1361 and the third pad connection line 1363, and the sixth pad connection line 1366 may be connected to the second pad connection line 1362 and the fourth pad connection line 1364. Accordingly, the first pad connection line 1361 and the third pad connection line 1363 extending in one direction may be electrically connected to each other, and the second pad connection line 1362 and the fourth pad connection line 1364 extending in one direction may be electrically connected to each other. Accordingly, the plurality of pad connection lines may electrically connect the first TSV 1375 and the third TSV 1377 and may electrically connect the second TSV 1376 and the fourth TSV 1378. That is, the first pad connection line 1361 and the third pad connection line 1363 may electrically connect the first TSV 1375 and the third TSV 1377, and the second pad connection line 1362 and the fourth pad connection line 1364 may electrically connect the second TSV 1376 and the fourth TSV 1378.

The first pad 1367 and the second pad 1368 may have substantially the same layout and connection relationship as the first pad 165 and the second pad 166 of FIG. 1. That is, the first pad 1367 and the second pad 1368 may be disposed to overlap a first trench capacitor 1321 and the second trench capacitor 1322 in the direction perpendicular to the first substrate 1311, the first pad 1367 may be connected to the first pad connection line 1361, the third pad connection line 1363, and the fifth pad connection line 1365, and the second pad 1368 may be connected to the second pad connection line 1362, the fourth pad connection line 1364, and the sixth pad connection line 1366. Accordingly, the first pad 1367 may be connected to the first trench capacitor 1321 and the second trench capacitor 1322 through various electrical paths including a plurality of pad connection lines 1361, 1363, and 1365 and the plurality of TSVs 1370 so that the ESR between the first pad 1367 and the first and second trench capacitors 1321 and 1322 can be improved.

Referring to FIG. 14, the plurality of TSVs 1370 may be disposed to pass through the second substrate 1312. Specifically, the plurality of TSVs 1370 may be disposed to pass through the second substrate 1312 between the metal pad layer 1360 and the third metal layer 1381 or between the metal pad layer 1360 and the fourth metal layer 1382. More specifically, the plurality of TSVs 1370 may be disposed to vertically pass through openings of the second substrate 1312 and the second trench capacitor 1322 between the metal pad layer 1360 and the third metal layer 1381 and between the metal pad layer 1360 and the fourth metal layer 1382.

The plurality of TSVs 1370 may include a fifth TSV 1375, a sixth TSV 1376, a seventh TSV 1377, and an eighth TSV 1378. Specifically, the plurality of TSVs 1370 may include the fifth TSV 1375 connected to the fifth metal pattern 1383, the sixth TSV 1376 connected to the sixth metal pattern 1384, the seventh TSV 1377 connected to the seventh metal pattern 1385, and the eighth TSV 1378 connected to the eighth metal pattern 1386. For example, the fifth TSV 1375 may be disposed between the metal pad layer 1360 and the fifth metal pattern 1383, the sixth TSV 1376 may be disposed between the metal pad layer 1360 and the sixth metal pattern 1384, the seventh TSV 1377 may be disposed between the metal pad layer 1360 and the seventh metal pattern 1385, and the eighth TSV 1378 may be disposed between the metal pad layer 1360 and the eighth metal pattern 1386. That is, each of the plurality of TSVs 1370 may directly connect any one of the third metal layer 1381 and the fourth metal layer 1382 to the metal pad layer 1360 in a direction perpendicular to one surface of the second substrate 1312. Since a plurality of metal patterns 1383, 1384, 1385, and 1386 are directly connected to different TSVs 1375, 1376, 1377, and 1378, the plurality of metal patterns 1383, 1384, 1385, and 1386 may be connected to the metal pad layer 1360 at the shortest distance. In addition, the metal pad layer 1360 may be vertically connected to the trench capacitors 1321 and 1322 through a plurality of TSVs 1375, 1376, 1377, and 1378 and the metal patterns 1383, 1384, 1385, and 1386 in an area overlapping the trench capacitors 1321 and 1322. Accordingly, since a connection distance between the trench capacitors 1321 and 1322 and the metal pad layer 1360 is reduced and a contact portion is increased, the ESR between the trench capacitors 1321 and 1322 and the metal pad layer 1360 can be improved.

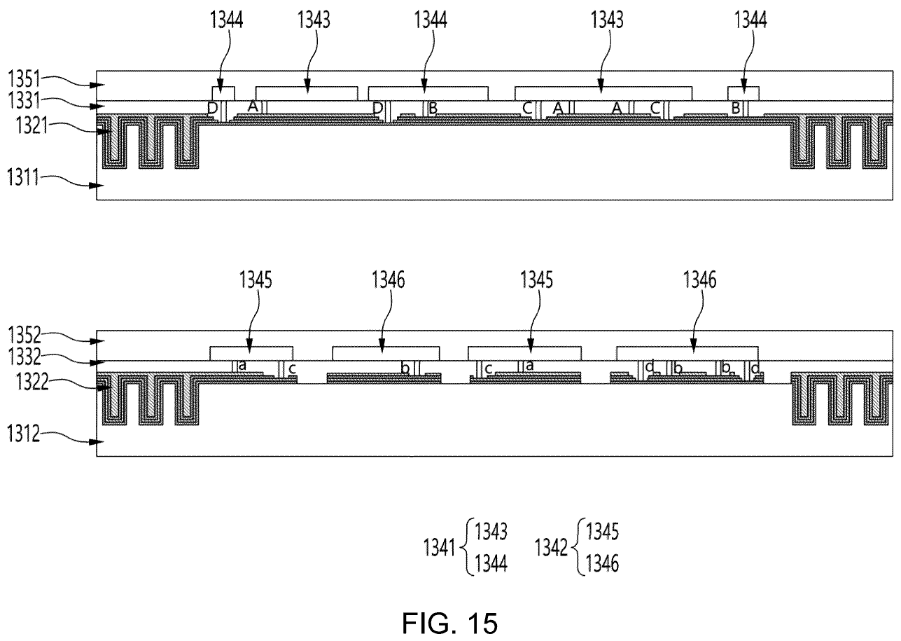

FIG. 15 is a cross-sectional view for describing a method of manufacturing a first metal layer and a second metal layer of a capacitor according to another embodiment of the present disclosure.

Referring to FIG. 15, a photolithography process apparatus and an etching process apparatus may form grooves in an upper surface of the first substrate 1311 and one surface of the second substrate 1312, and a deposition process apparatus may form the first trench capacitor 1321 on the upper surface of the first substrate 1311 and may form the second trench capacitor 1322 on one surface of the second substrate 1312. A method of forming the grooves in the upper surface of the first substrate 1311 and one surface of the second substrate 1312, forming the first trench capacitor 1321 on the upper surface of the first substrate 1311, and forming the second trench capacitor 1322 on one surface of the second substrate 1312 may be substantially the same as an operation of forming the grooves in the upper surface of the first substrate 111 and one surface of the second substrate 112 of FIG. 1, forming the first trench capacitor 121 on the upper surface of the first substrate 111, and forming the second trench capacitor 122 on the upper surface of the second substrate 112.

In some cases, in an operation of forming the grooves in the upper surface of the first substrate 1311 and one surface of the second substrate 1312, an alignment key (not shown) may be formed in a scribe lane of an upper surface of the second substrate 1312. A method of forming the alignment key in the scribe lane of the upper surface of the second substrate 1312 may be substantially the same as a method of forming the alignment key 115 in the second substrate 112 of FIGS. 5 and 6. In addition, the alignment key formed on the second substrate 1312 may have substantially the same shape as the alignment key 115 formed on the second substrate 112 of FIGS. 5 and 6.

According to various embodiments of the present disclosure, in the operation of forming the grooves in the upper surface of the first substrate 1311 and one surface of the second substrate 1312, the alignment key may be formed in a capacitor design area of the second substrate 1312. That is, at least one of a plurality of trenches disposed in the capacitor design area of the second substrate 1312 may be formed to have a relatively great width or a relatively great length. A method of forming the alignment key in the capacitor design area of the second substrate 1312 may be substantially the same as a method of forming the alignment key 115 in the capacitor design area of the second substrate 112 of FIGS. 5 and 6. In addition, the shape and layout of the alignment key formed in the capacitor design area of the second substrate 1312 may be substantially the same as the shape and layout of the alignment key 115 formed in the capacitor design area of the second substrate 112 of FIGS. 5 and 6.

Referring to FIG. 15, a plurality of openings may be formed in the second trench capacitor 1322. Specifically, the photolithography process apparatus and the etching process apparatus may etch portions of the second trench capacitor 1322 to form the openings passing through the second trench capacitor 1322.

In a process of forming the openings, the second trench capacitor 1322 may be etched using the alignment key. Specifically, positions at which the plurality of openings of the second trench capacitor 1322 are formed may be determined based on the alignment key. For example, a vision camera may sense the alignment key, and an alignment module may determine the positions, at which the plurality of openings are formed, based on the position of the alignment key and may align a mask at the determined positions at which the plurality of openings are formed. The photolithography process apparatus and the etching process apparatus may form the openings passing through the second trench capacitor 1322 by patterning a photoresist at a position determined through the aligned mask and etching the second trench capacitor 1322. The vision camera and the alignment module may be disposed in each semiconductor process apparatus or may be an independent device separate from the semiconductor process apparatus. Preferably, the vision camera and the alignment module may be included in each of the photolithography process apparatus and an etching apparatus. Since a process of forming the plurality of openings includes a process of aligning the mask through the alignment key, the plurality of openings may be formed more accurately at pre-designed positions. In addition, by using the alignment key, the second trench capacitor 1322 is etched, and the plurality of openings are formed, thereby improving the consistency of positions of the plurality of trenches and the plurality of openings and minimizing the influence of process errors.

Referring to FIG. 15, the photolithography process apparatus and the etching process apparatus may form contact holes by etching at least some of the first insulating layer, the second electrode, the second insulating layer, the third electrode, the third insulating layer, and the fourth electrode of the first trench capacitor 1321 and the second trench capacitor 1322. Specifically, in the first trench capacitor 1321, a B contact hole in which the third insulating layer and the fourth electrode are etched in an area B to expose the third electrode, a C contact hole in which the second insulating layer, the third electrode, the third insulating layer, and the fourth electrode are etched in an area C to expose the second electrode, and a D contact hole in which the first insulating layer, the second electrode, the second insulating layer, the third electrode, the third insulating layer, and the fourth electrode are etched in an area D to expose the first electrode may be formed. In the second trench capacitor 1322, a b contact hole in which the third insulating layer and the fourth electrode are etched in an area b to expose the third electrode, a c contact hole in which the second insulating layer, the third electrode, the third insulating layer, and the fourth electrode are etched in an area c to expose the second electrode, and a d contact hole in which the first insulating layer, the second electrode, the second insulating layer, the third electrode, the third insulating layer, and the fourth electrode are etched in an area d to expose the first electrode may be formed. A structure and forming method of the B contact hole, the C contact hole, the D contact hole, the b contact hole, the c contact hole, and the d contact hole may be substantially the same as a structure and forming method of the B contact hole, the C contact hole, the D contact hole, the b contact hole, the c contact hole, and the d contact hole of FIGS. 8 and 9.

Referring to FIG. 15, the deposition process apparatus may form the first dielectric layer 1331 on the first trench capacitor 1321 and may form the second dielectric layer 1332 on the second trench capacitor 1322. The photolithography process apparatus and the etching process apparatus may form a first through-hole in each of the first dielectric layer 1331 and the second dielectric layer 1332. Specifically, the photolithography process apparatus and the etching process apparatus may form a plurality of first through-holes that are connected to respective electrodes of the first trench capacitor 1321 and the second trench capacitor 1322 and pass through the first dielectric layer 1331 and the second dielectric layer 1332. A method of forming the first dielectric layer 1331, the second dielectric layer 1332, and the plurality of first through-holes, and a structure of the plurality of first through-holes may be substantially the same as a method of forming the first dielectric layer 131, the second dielectric layer 132, and the plurality of first through-holes, and a structure of the plurality of first through-holes of FIGS. 8 and 9.

Referring to FIG. 15, the first metal layer 1341 may be formed on the first dielectric layer 1331 to cover the first through-hole and connect to the first trench capacitor 1321, and the second metal layer 1342 may be formed on the second dielectric layer 1332 to cover the first through-hole and connect to the second trench capacitor 1322. Specifically, the deposition process apparatus may form a metal layer on the first dielectric layer 1331 and the second dielectric layer 1332, and the photolithography process apparatus and the etching process apparatus may pattern each of the first metal layer 1341 and the second metal layer 1342.

The deposition process apparatus may form the third dielectric layer 1351 to cover the first metal layer 1341 on the first dielectric layer 1331 and may form the fourth dielectric layer 1352 to cover the second metal layer 1342 on the second dielectric layer 1332. A method of forming the first metal layer 1341, the second metal layer 1342, the third dielectric layer 1351, and the fourth dielectric layer 1352 may be substantially the same as a method of forming the first dielectric layer 131, the second dielectric layer 132, the first metal layer 141, and the second metal layer 142 of FIGS. 8 and 9.

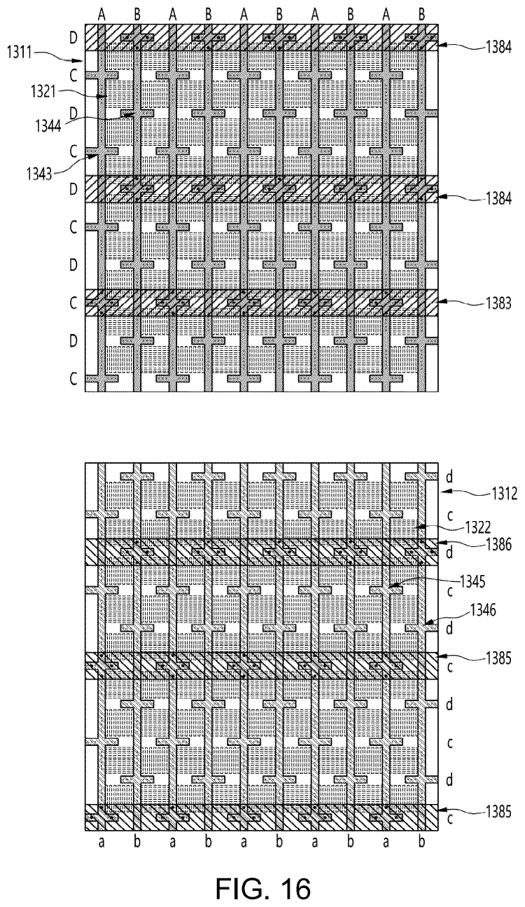

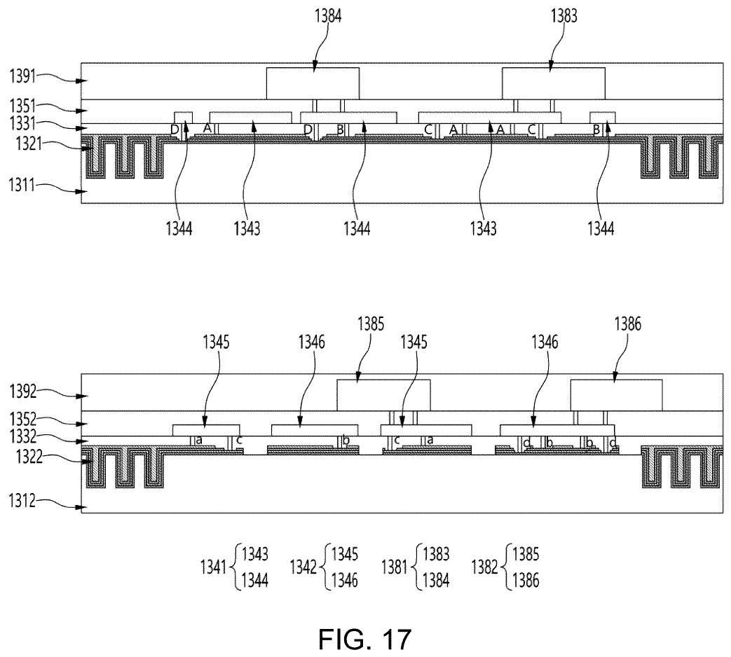

FIG. 16 is a top view for describing a method of manufacturing a third metal layer and a fourth metal layer of a capacitor according to another embodiment of the present disclosure. FIG. 17 is a cross-sectional view for describing the method of manufacturing a third metal layer and a fourth metal layer of FIG. 16.

Referring to FIGS. 16 and 17, a second through-hole may be formed in each of the third dielectric layer 1351 and the fourth dielectric layer 1352. Specifically, the photolithography process apparatus and the etching process apparatus may form a plurality of second through-holes passing through the third dielectric layer 1351 and connected to the first metal layer 1341 and a plurality of second through-holes passing through the fourth dielectric layer 1352 and connected to the second metal layer 1342.

The plurality of second through-holes may include a plurality of second through-holes connected to long pattern portions of the first metal layer 1341 and the second metal layer 1342 or a plurality of second through-holes connected to the short pattern portions of the first metal layer 1341 and the second metal layer 1342. In some cases, the short pattern portions of the first metal layer 1341 and the second metal layer 1342 may have a relatively great width compared to the long pattern portions of the first metal layer 1341 and the second metal layer 1342 so that the plurality of second through-holes may only include the plurality of second through-holes connected to the short pattern portions of the first metal layer 1341 and the second metal layer 1342. That is, the plurality of second through-holes may not be directly connected to the long pattern portions of the first metal layer 1341 and the second metal layer 1342. Accordingly, it is possible to prevent problems that may occur due to process errors in a process of connecting the second through-holes to the long pattern portions of the first metal layer 1341 and the second metal layer 1342 which have a relatively narrow width.

Referring to FIGS. 16 and 17, the third metal layer 1381 may be formed on the third dielectric layer 1351, and the fourth metal layer 1382 may be formed on the fourth dielectric layer 1352. Specifically, the third metal layer 1381 may be formed on the third dielectric layer 1351 to cover the second through-hole and connect to the first metal layer 1341, and the fourth metal layer 1382 may be formed on the fourth dielectric layer 1352 to cover the second through-hole and connect to the second metal layer 1342. More specifically, the deposition process apparatus may form a metal layer on the third dielectric layer 1351 and the fourth dielectric layer 1352, and the photolithography process apparatus and the etching process apparatus may pattern the third metal layer 1381 and the fourth metal layer 1382. That is, the photolithography process apparatus and the etching process apparatus may form the third metal layer 1381 and the fourth metal layer 1382 by patterning the metal layer disposed on the third dielectric layer 1351 and the fourth dielectric layer 1352.

Referring to FIG. 17, the fifth dielectric layer 1391 may be formed to cover the third metal layer 1381 on the third dielectric layer 1351, and the sixth dielectric layer 1392 may be formed to cover the fourth metal layer 1382 on the fourth dielectric layer 1352. More specifically, the deposition process apparatus may form the fifth dielectric layer 1391 on the third dielectric layer 1351 and the third metal layer 1381 and may form the sixth dielectric layer 1392 on the fourth dielectric layer 1352 and the fourth metal layer 1382.

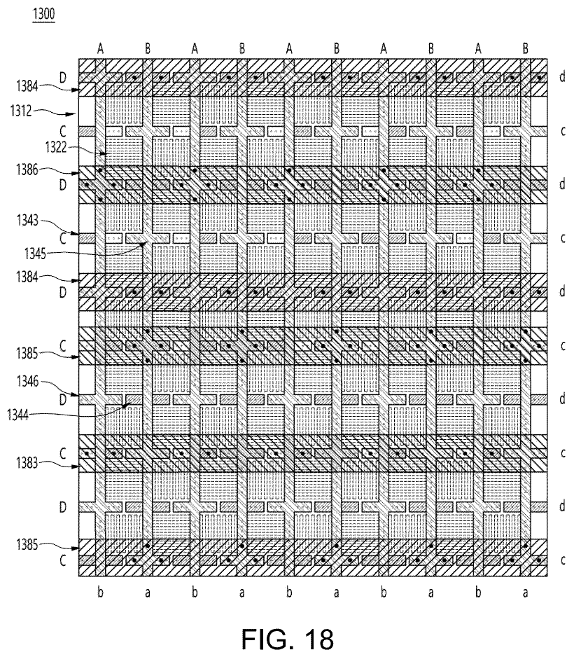

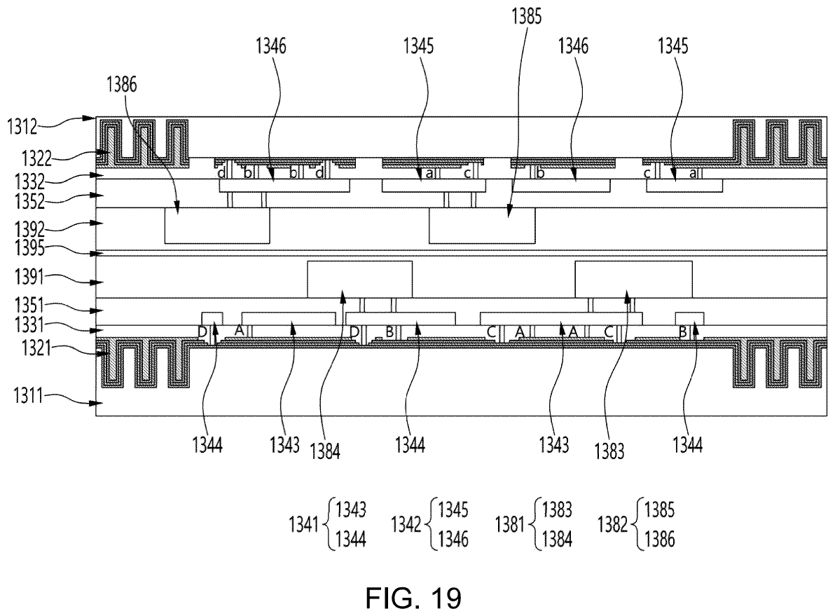

FIG. 18 is a top view for describing a method of bonding a first substrate and a second substrate of a capacitor according to another embodiment of the present disclosure. FIG. 19 is a cross-sectional view for describing the method of bonding the first substrate and the second substrate of FIG. 18.

Referring to FIGS. 18 and 19, the first substrate 1311 and the second substrate 1312 may be bonded in the direction perpendicular to the first substrate 1311. Specifically, the fifth dielectric layer 1391 and the sixth dielectric layer 1392 may be bonded such that the upper surface of the first substrate 1311 and one surface of the second substrate 1312 face each other. More specifically, an upper surface of the fifth dielectric layer 1391 on the first substrate 1311 and an upper surface of the sixth dielectric layer 1392 on the second substrate 1312 may be bonded to face each other. For example, the fifth dielectric layer 1391 and the sixth dielectric layer 1392 may be bonded at the bonding layer 1395 through any one of adhesive bonding, oxide bonding, and fusion bonding. When the third dielectric layer 1351 and the fourth dielectric layer 1352 are bonded through adhesive bonding, the bonding layer 1395 may include an adhesive. Specifically, an adhesive layer may be disposed on the third dielectric layer 1351, and the first substrate 1311 and the second substrate 1312 may be bonded to each other such that the fourth dielectric layer 1352 is located on the adhesive layer. A method of bonding the fifth dielectric layer 1391 and the sixth dielectric layer 1392 at the bonding layer 1395 may be substantially the same as a method of bonding the third dielectric layer 151 and the fourth dielectric layer 152 at the bonding layer 155 of FIGS. 10 and 11.

Referring to FIG. 19, the second substrate 1312 bonded to the first substrate 1311 may be thinned. Specifically, a thickness of the second substrate 1312 may be reduced from the other surface opposite to one surface of the second substrate 1312 on which the second trench capacitor 1322 is disposed. For example, a thinning process apparatus may reduce the thickness of the second substrate 1312 from the upper surface of the second substrate 1312 bonded to the first substrate 1311. The thinning process apparatus may include any one of a CMP device, a mechanical polishing device, and a wet or dry etching device. By thinning the second substrate 1312, a plurality of grooves of the second trench capacitor 1322 disposed in the second substrate 1312 or the alignment key disposed in the scribe lane of the second substrate 1312 may be sensed on the upper surface of the second substrate 1312.

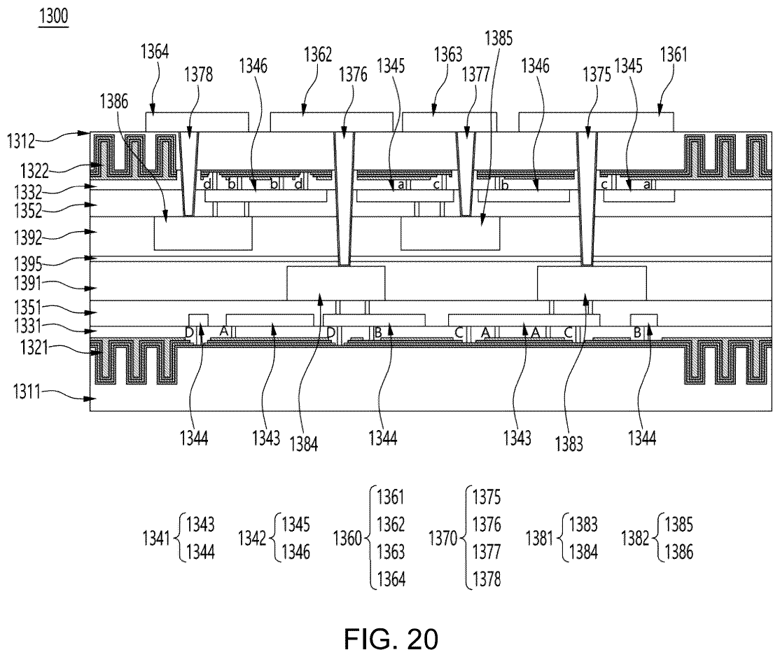

FIG. 20 is a cross-sectional view for describing a method of manufacturing a plurality of TSVs and a metal pad layer of a capacitor according to another embodiment of the present disclosure.

Referring to FIG. 20, the plurality of TSVs 1370 passing through the second substrate 1312 may be formed. Specifically, the photolithography process apparatus and the etching process apparatus may pattern a photoresist to determine arrangement positions and sizes of the plurality of TSVs 1370, and a drilling process apparatus or the etching process apparatus may form holes passing through the second substrate 1312 at a position at which the photoresist is patterned. The deposition process apparatus may form the plurality of TSVs 1370 by depositing a conductive material inside the holes passing through the second substrate 1312.

A vision camera of the photolithography process apparatus may sense a position of the alignment key disposed in the scribe lane on the upper surface of the second substrate 1312, and the alignment module may recognize positions, at which a plurality of openings are formed, based on the position of the sensed alignment key and may determine the position at which the photoresist is patterned. The drilling process apparatus or the etching process apparatus may form the plurality of TSVs 1370 at the positions at which the plurality of openings are formed. Specifically, the drilling process apparatus or the etching process apparatus may form the holes passing through the second substrate 1312 at the positions at which the plurality of openings are formed, and the deposition process apparatus may form the TSV 1370 by depositing a conductive material inside the holes passing through the second substrate 1312.

In some cases, the vision camera of the photolithography process apparatus may sense the second trench capacitor 1322 on the upper surface of the second substrate 1312. Specifically, the vision camera may sense positions of a plurality of grooves of the second trench capacitor 1322 and a position of the alignment key disposed in a capacitor design area. The alignment module may recognize the positions, at which the plurality of openings are formed, based on the sensed position of the second trench capacitor 1322. Specifically, the alignment module may recognize the positions, at which the plurality of openings are formed, based on the plurality of grooves of the sensed second trench capacitor 1322 and the position of the alignment key disposed in the capacitor design area and may determine the position at which the photoresist is patterned. The drilling process apparatus or the etching process apparatus may form the plurality of TSVs 1370 at the positions at which the plurality of openings are formed. Specifically, the drilling process apparatus or the etching process apparatus may form the holes passing through the second substrate 1312 at the positions at which the plurality of openings are formed, and the deposition process apparatus may form the TSV 1370 by depositing a conductive material inside the holes passing through the second substrate 1312.

Referring to FIG. 20, the metal pad layer 1360 connected to the plurality of TSVs 1370 may be formed on the other surface of the second substrate 1312. Specifically, the metal pad layer 1360 may be formed on the other surface located opposite to one surface of the second substrate 1312 on which the second trench capacitor 1322 is disposed. More specifically, as shown in FIG. 20, the deposition process apparatus may deposit a conductive layer to cover the plurality of TSVs 1370 on the upper surface of the second substrate 1312, and the photolithography process apparatus and the etching process apparatus may form the metal pad layer 1360 by patterning the conductive layer disposed on the upper surface of the second substrate 1312.

The capacitor 1300 according to the present embodiment may include the third and fourth metal layers 1381 and 1382 having a greater width than the first and second metal layers 1341 and 1342 so that the plurality of TSVs 1370 disposed between the metal pad layer 1360 and the third and fourth metal layers 1381 and 1382 may have a greater width. Accordingly, by increasing the contact area between the metal pad layer 1360 and the third and fourth metal layers 1381 and 1382, the ESR between the metal pad layer 1360 and the third and fourth metal layers 1381 and 1382 can be improved.

In addition, the capacitor 1300 according to the present embodiment includes the third and fourth metal layers 1381 and 1382 having a greater width than the first and second metal layers 1341 and 1342, thereby preventing problems due to process errors that may occur in a process of connecting the plurality of TSVs 1370 to the first and second metal layers 1341 and 1342 having a relatively small width.

According to any one of the means for solving the problems of the present disclosure, a capacitor can have higher equivalent capacitance by including a first trench capacitor and a second trench capacitor, which are connected in parallel. In particular, according to any one of the means for solving the problems of the present disclosure, a capacitor can secure higher capacitance and higher charge/current density in the same area by vertically stacking and bonding at least two trench capacitors.

According to any one of the means for solving the problems of the present disclosure, a capacitor can include a plurality of TSVs passing through a plurality of openings of a second trench capacitor so that contact paths from front surfaces of first and second trench capacitors to a metal pad layer can be uniformly distributed, and a contact area can be increased.

According to any one of the means for solving the problems of the present disclosure, a capacitor can include a plurality of TSVs connecting first and second metal layers and a metal pad layer on front surfaces of first and second trench capacitors so that a length of a connection line between the first and second trench capacitors and first and second pads can be reduced, and the uniformity of a contact path, the density of contact holes, and a contact area can be increased. In particular, such a capacitor can be provided such that a plurality of TSVs for electrically connecting a first trench capacitor and a second trench capacitor are disposed at specific intervals in a plane view. Thus, a plurality of TSVs can be uniformly distributed across an entire planar surface of a capacitor without being concentrated in an outer area or specific area of the capacitor. Accordingly, in a capacitor according to any one of the means for solving the problems of the present disclosure, a length of a connection line for connecting two trench capacitors vertically disposed can be reduced.

According to any one of the means for solving the problems of the present disclosure, in a method of manufacturing a capacitor, by simultaneously performing an operation of forming a groove in one surface of a second substrate and an operation of forming an alignment key in a scribe lane of the second substrate, a separate manufacturing process of forming the alignment key can be omitted, thereby reducing a manufacturing cost and time.

According to any one of the means for solving the problems of the present disclosure, a capacitor can include third and fourth metal layers having a greater width than first and second metal layers so that a plurality of TSVs disposed between a metal pad layer and the third and fourth metal layers can have a greater width.

According to any one of the means for solving the problems of the present disclosure, since a capacitor includes a plurality of TSVs having a greater width between a metal pad layer and third and fourth metal layers, thereby improving the ESR characteristics between the metal pad layer and the third and fourth metal layers.

The effects obtainable in the present disclosure are not limited to the effects described above, and other effects that are not described will be clearly understood by a person skilled in the art from the description below.

Although embodiments of the present disclosure have been described in more detail with reference to the accompanying drawings, the present disclosure is not necessarily limited to these embodiments, and various modifications may be made without departing from the technical spirit of the present disclosure. Accordingly, the embodiments disclosed in the present disclosure are not intended to limit the technical idea of the present disclosure but are for illustrative purposes, and the scope of the technical idea of the present disclosure is not limited by these embodiments. Accordingly, it should be understood that the above-described embodiments are exemplary in all respects and not restrictive. The spirit and scope of the present disclosure should be interpreted by the appended claims and encompass all equivalents falling within the scope of the appended claims.

What is claimed is:

1. A capacitor comprising:
a first substrate;
a second substrate disposed on the first substrate;
a first trench capacitor disposed on an upper surface of the first substrate;
a second trench capacitor disposed on one surface of the second substrate;
a first metal layer connected to the first trench capacitor;
a second metal layer connected to the second trench capacitor;
a plurality of through-silicon vias (TSVs) passing through the second substrate; and
a metal pad layer disposed on the other surface opposite to the one surface of the second substrate,
wherein the upper surface and the one surface are disposed to face each other, and
each of the plurality of TSVs directly connects one of the first metal layer and the second metal layer to the metal pad layer in a direction perpendicular to the one surface.

2. The capacitor of claim 1, wherein the first metal layer includes a first metal pattern connected to a second electrode of the first trench capacitor and a second metal pattern connected to a first electrode of the first trench capacitor,
the second metal layer includes a third metal pattern connected to a second electrode of the second trench capacitor and a fourth metal pattern connected to a first electrode of the second trench capacitor, and
the plurality of TSVs include a first TSV connected to the first metal pattern, a second TSV connected to the second metal pattern, a third TSV connected to the third metal pattern, and a fourth TSV connected to the fourth metal pattern.

3. The capacitor of claim 2, wherein each of the first trench capacitor and the second trench capacitor further includes a third electrode and a fourth electrode,
the first metal pattern is connected to the fourth electrode of the first trench capacitor,
the second metal pattern is connected to the third electrode of the first trench capacitor,
the third metal pattern is connected to the fourth electrode of the second trench capacitor, and
the fourth metal pattern is connected to the third electrode of the second trench capacitor.

4. The capacitor of claim 2, wherein the metal pad layer includes a plurality of pad connection lines, and
the plurality of pad connection lines are disposed to overlap the first trench capacitor and the second trench capacitor in the direction perpendicular to the one surface, electrically connect the first TSV and the third TSV, and electrically connect the second TSV and the fourth TSV.

5. The capacitor of claim 1, further comprising openings passing through the second trench capacitor in the direction perpendicular to the one surface,
wherein the plurality of TSVs are disposed to pass through the openings.

6. A capacitor comprising:
a first substrate;
a second substrate disposed on the first substrate;
a first trench capacitor disposed on an upper surface of the first substrate;
a second trench capacitor disposed on one surface of the second substrate;
a first metal layer connected to the first trench capacitor;
a second metal layer connected to the second trench capacitor;
a third metal layer connected to the first metal layer;
a fourth metal layer connected to the second metal layer;
a plurality of through-silicon vias (TSVs) passing through the second substrate; and
a metal pad layer disposed on the other surface opposite to the one surface of the second substrate,
wherein the upper surface and the one surface are disposed to face each other, and
each of the plurality of TSVs directly connects one of the third metal layer and the fourth metal layer to the metal pad layer in a direction perpendicular to the one surface.

7. The capacitor of claim 6, wherein the first metal layer includes a first metal pattern connected to a second electrode of the first trench capacitor and a second metal pattern connected to a first electrode of the first trench capacitor,
the second metal layer includes a third metal pattern connected to a second electrode of the second trench capacitor and a fourth metal pattern connected to a first electrode of the second trench capacitor,
the third metal layer includes a fifth metal pattern connected to the first metal pattern and a sixth metal pattern connected to the second metal pattern,
the fourth metal layer includes a seventh metal pattern connected to the third metal pattern and an eighth metal pattern connected to the fourth metal pattern, and
the plurality of TSVs include a fifth TSV connected to the fifth metal pattern, a sixth TSV connected to the sixth metal pattern, a seventh TSV connected to the seventh metal pattern, and an eighth TSV connected to the eighth metal pattern.

8. The capacitor of claim 7, wherein each of the first trench capacitor and the second trench capacitor further includes a third electrode and a fourth electrode,
the first metal pattern is connected to the fourth electrode of the first trench capacitor,
the second metal pattern is connected to the third electrode of the first trench capacitor,
the third metal pattern is connected to the fourth electrode of the second trench capacitor, and
the fourth metal pattern is connected to the third electrode of the second trench capacitor.

9. The capacitor of claim 7, wherein the metal pad layer includes a plurality of pad connection lines, and
the plurality of pad connection lines are disposed to overlap the first trench capacitor and the second trench capacitor in the direction perpendicular to the one surface, electrically connect the fifth TSV and the seventh TSV, and electrically connect the sixth TSV and the eighth TSV.

10. The capacitor of claim 6, further comprising openings passing through the second trench capacitor in the direction perpendicular to the one surface,
wherein the plurality of TSVs are disposed to pass through the openings.

11. A method of manufacturing a capacitor, the method comprising:
forming grooves in an upper surface of a first substrate and one surface of a second substrate;
forming a first trench capacitor on the upper surface and forming a second trench capacitor on the one surface;
etching portions of the second trench capacitor to form openings passing through the second trench capacitor;
forming a first dielectric layer on the first trench capacitor and forming a second dielectric layer on the second trench capacitor;
forming a through-hole in each of the first dielectric layer and the second dielectric layer;
forming a first metal layer on the first dielectric layer to cover the through-hole and connect to the first trench capacitor, and forming a second metal layer on the second dielectric layer to cover the through-hole and connect to the second trench capacitor;
patterning each of the first metal layer and the second metal layer;
forming a third dielectric layer to cover the first metal layer on the first dielectric layer, and forming a fourth dielectric layer to cover the second metal layer on the second dielectric layer;
bonding the third dielectric layer and the fourth dielectric layer such that the upper surface and the one surface face each other;
reducing a thickness of the second substrate from the other surface opposite to the one surface;
forming a plurality of through-silicon vias (TSVs) passing through the second substrate; and
forming a metal pad layer connected to the plurality of TSVs on the other surface.

12. The method of claim 11, wherein the forming of the grooves includes forming an alignment key in a scribe lane of the second substrate.

13. The method of claim 12, wherein the forming of the openings includes etching the second trench capacitor using the alignment key.

14. The method of claim 12, wherein the forming of the plurality of TSVs includes:
sensing the alignment key on the other surface;
recognizing positions, at which the openings are formed, based on a position of the alignment key; and
forming the plurality of TSVs at the positions at which the openings are formed.

15. The method of claim 12, wherein the forming of the TSVs includes:
sensing the second trench capacitor on the other surface;
recognizing positions, at which the openings are formed, based on the position of the sensed second trench capacitor; and
forming the plurality of TSVs at the positions at which the openings are formed.

16. The method of claim 11, wherein the bonding of the third dielectric layer and the fourth dielectric layer includes:
arranging an adhesive layer on the third dielectric layer; and
bonding the first substrate and the second substrate to each other such that the fourth dielectric layer is positioned on the adhesive layer.

17. A method of manufacturing a capacitor, the method comprising:
forming grooves in an upper surface of a first substrate and one surface of a second substrate;
forming a first trench capacitor on the upper surface and forming a second trench capacitor on the one surface;
etching portions of the second trench capacitor to form openings passing through the second trench capacitor;
forming a first dielectric layer on the first trench capacitor and forming a second dielectric layer on the second trench capacitor;
forming a first through-hole in each of the first dielectric layer and the second dielectric layer;
forming a first metal layer on the first dielectric layer to cover the first through-hole and connect to the first trench capacitor, and forming a second metal layer on the second dielectric layer to cover the first through-hole and connect to the second trench capacitor;
patterning each of the first metal layer and the second metal layer;
forming a third dielectric layer to cover the first metal layer on the first dielectric layer, and forming a fourth dielectric layer to cover the second metal layer on the second dielectric layer;
forming a second through-hole in each of the third dielectric layer and the fourth dielectric layer;
forming a third metal layer on the third dielectric layer to cover the second through-hole and connect to the first metal layer, and forming a fourth metal layer on the fourth dielectric layer to cover the second through-hole and connect to the second metal layer;
patterning the third metal layer and the fourth metal layer;
forming a fifth dielectric layer to cover the third metal layer on the third dielectric layer, and forming a sixth dielectric layer to cover the fourth metal layer on the fourth dielectric layer;
bonding the fifth dielectric layer and the sixth dielectric layer such that the upper surface and the one surface face each other;
reducing a thickness of the second substrate from the other surface opposite to the one surface;
forming a plurality of through-silicon vias (TSVs) passing through the second substrate; and
forming a metal pad layer connected to the plurality of TSVs on the other surface.

18. The method of claim 17, wherein the forming of the grooves includes forming an alignment key in a scribe lane of the second substrate.

19. The method of claim 18, wherein the forming of the openings includes etching the second trench capacitor using the alignment key.

20. The method of claim 18, wherein the forming of the plurality of TSVs includes:
sensing the alignment key on the other surface;
recognizing positions, at which the openings are formed, based on a position of the alignment key; and
forming the plurality of TSVs at the positions at which the openings are formed.

21. The method of claim 18, wherein the forming of the TSVs includes:
sensing the second trench capacitor on the other surface;
recognizing positions, at which the openings are formed, based on the position of the sensed second trench capacitor; and
forming the plurality of TSVs at the positions at which the openings are formed.

22. The method of claim 17, wherein the bonding of the fifth dielectric layer and the sixth dielectric layer includes:
arranging an adhesive layer on the fifth dielectric layer; and
bonding the first substrate and the second substrate to each other such that the sixth dielectric layer is positioned on the adhesive layer.
